(19) United States
(12) Patent Application Publication
(10) Pub. No.: US 2018/0004086 A1
(43) Pub. Date: Jan. 4, 2018

(54) NEGATIVE PHOTOSENSITIVE RESIN COMPOSITION, PRODUCTION METHOD OF SPACER, PRODUCTION METHOD OF PROTECTION FILM, AND LIQUID CRYSTAL DISPLAY DEVICE

(71) Applicant: Chi Mei Corporation, Tainan City (TW)

(72) Inventors: I-kuang Chen, New Taipei City (TW); Hao-Wei Liao, Kaohsiung City (TW)

(73) Assignee: Chi Mei Corporation, Tainan City (TW)

(21) Appl. No.: 15/628,630

(22) Filed: Jun. 20, 2017

(30) Foreign Application Priority Data
Jun. 29, 2016 (TW) 105120477

(51) Int. Cl. G03F 7/038; G03F 7/38; G03F 7/075; G03F 7/028; G03F 7/004; G03F 7/40; G02F 1/1335

(52) U.S. Cl. CPC G03F 7/0382; G03F 7/40; G03F 7/38; G02F 1/133528; G03F 7/028; G03F 7/0045; G03F 7/0755

(57) ABSTRACT

A negative photosensitive resin composition including an alkali-soluble resin (A), a compound (B) containing an ethylenically-unsaturated group, a photoinitiator (C), a solvent (D), and a silicone compound (E) is provided. The silicone compound (E) contains the structure represented by formula (E-1). The negative photosensitive resin composition has good sputtering resistance, by using the negative photosensitive resin composition, the issue of poor sputtering resistance of the spacer or a protective film formed by the negative photosensitive resin composition can be solved.

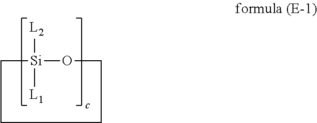

### CROSS-REFERENCE TO RELATED APPLICATION

This application claims the priority benefit of Taiwan application serial no. 105120477, filed on Jun. 29, 2016. The entirety of the above-mentioned patent application is hereby incorporated by reference herein and made a part of this specification.

### BACKGROUND OF THE INVENTION

### Field of the Invention

The invention relates to a negative photosensitive resin composition, a production method of a spacer, a production method of a protective film, and a liquid crystal display device, and more particularly, to a negative photosensitive resin composition capable of providing good sputtering resistance, a production method of a spacer or a protective film formed by the negative photosensitive resin composition, and a liquid crystal display device containing the spacer or the protective film.

### Description of Related Art

In general, the uneven places generated by the pixels and a black matrix of color printing of a color filter layer surface are formed into a protective film on the surface of the color filter layer, so as to hide the uneven places to achieve the demand of a flat surface.

However, during the production of an optical device such as a liquid crystal display device or a solid imaging apparatus, treatments under harsh conditions are performed, such as when a wiring electrode layer is formed on a substrate surface via sputtering, localized corrosion or high temperature occurs. Therefore, a protective film needs to be provided on the surface of the devices to prevent damage to the devices during production. To provide the protective film with characteristics against the treatments, the protective film needs to have excellent adhesion with the substrate, and high sputtering resistance.

Moreover, in prior art, in a color liquid crystal display device, to maintain the fixed spacing between two substrates (cell gap), polystyrene beads or silicon beads are randomly sprayed on the entire substrate, wherein the diameter of the beads is the spacing between the two substrates. However, since the locations and density distribution of the sprayed beads are not uniform in the known method, the light of the backlight is affected by the sprayed beads and scattered, such that the contrast of the display device is reduced as a result. Therefore, a photosensitive composition for a spacer developed via a photolithography method is gradually becoming the mainstream in the industry. The forming method of the spacer includes first coating the photosensitive composition for the spacer on a substrate, and then placing a photomask having a specified shape between the substrate and the exposure source, and a spacer can be formed via development after exposure. Based on this method, a spacer can be formed on a specified location outside the red (R), green (G), and blue (B) pixels to solve the issues of the prior art; the cell gap can also be controlled using the coating thickness of the photosensitive component, such that the distance of the cell gap is readily controlled and the advantage of high precision is achieved.

Since the protective film or the spacer is formed on the color filter or substrate, the demand for transparency is very high. If the transparency of the protective film or the spacer is poor, then when applied in a liquid crystal display device, the brightness of the liquid crystal display device is poor, such that the display quality of the liquid crystal display device is affected. To increase the transparency of the protective film or the spacer, JP 2004-240241 discloses a negative photosensitive composition containing a copolymer (A), and the copolymer is obtained by copolymerizing an ethylenically-unsaturated carboxylic acid (anhydride), a compound of an ethylenically-unsaturated group having an epoxy group, and compounds of other ethylenically-unsaturated groups; a polymer (B) of an ethylenically-unsaturated group; and a photoinitiator (C), including 2-butanedione-[4-methylthio phenyl]-2-(O-oxime acetate), 1,2-diacetyl-1-(4-morpholinophenyl)-2-(O-benzoyl oxime), 1,2-octanedione-1-[4-phenylthio phenyl]-2-[O-(4-methyl-benzoyl)oxime], or a similar compound thereof.

However, in the production of the wiring electrode layer, the spacer or the protective film made by the negative photosensitive composition is in low pressure and sputtered in the applied plasma environment, and therefore issues such as reduced film thickness and outgassing occur. As a result, the increase of sputtering resistance is an issue that urgently needs to be solved.

### SUMMARY OF THE INVENTION

Accordingly, the invention provides a negative photosensitive resin composition capable of providing good sputtering resistance, and by using the negative photosensitive resin composition, the issue of poor sputtering resistance of the spacer or a protective film formed by the negative photosensitive resin composition can be solved.

The invention provides a negative photosensitive resin composition including an alkali-soluble resin (A), a compound (B) containing an ethylenically-unsaturated group, a photoinitiator (C), a solvent (D), and a silicone compound (E). The silicone compound (E) contains the structure represented by formula (E-1):

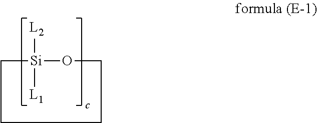

In formula (E-1), c is an integer of 3 to 7; L₁ and L₂ each independently represent a monovalent group containing an epoxy ester ring group or an alkyl group, a plurality of L₁ and L₂ can be the same or different, and in a c number of L₁ and L₂, at least one group is a monovalent group containing an epoxy ester ring group.

In an embodiment of the invention, the alkali-soluble resin (A) includes a first alkali-soluble resin (A-1), and the first alkali-soluble resin (A-1) has a repeating unit represented by formula (A1-1):

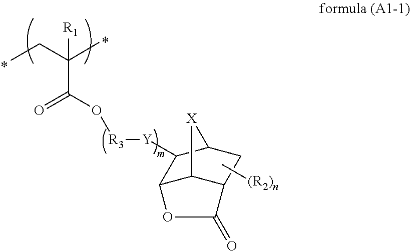

In formula (A1-1), R₁ represents a hydrogen atom or an alkyl group; R₂ represents an alkyl group, a cycloalkyl group, an alkoxy group, an alkoxycarbonyl group, a carboxyl group, a halogen atom, a hydroxyl group, or a cyano group; R₃ represents an alkylene group, a cycloalkylene group, or a combination thereof, and when formula (A1-1) has 2 or more R₃, each R₃ can be the same or different. Y represents a single bond, —O—, —COO—, —CONH—, —NHCOO—, or —NHCONH—, when formula (A1-1) has 2 or more Y, each Y can be the same or different; X represents methylene, methyl methylene, dimethyl methylene, ethylene, —O—, or —S—. m and n each independently represent an integer of 0 to 4, when n is 2 or more, an n number of R₂ can be the same or different; * represents a bonding site.

In an embodiment of the invention, the first alkali-soluble resin (A-1) has an ethylenically-unsaturated group.

In an embodiment of the invention, the negative photosensitive resin composition further includes a photoacid generator (F).

In an embodiment of the invention, based on a usage amount of 100 parts by weight of the alkali-soluble resin (A), the usage amount of the compound (B) containing an ethylenically-unsaturated group is 30 parts by weight to 300 parts by weight, the usage amount of the photoinitiator (C) is 10 parts by weight to 80 parts by weight, the usage amount of the solvent (D) is 500 parts by weight to 3000 parts by weight, and the usage amount of the silicone compound (E) is 3 parts by weight to 25 parts by weight.

In an embodiment of the invention, based on a usage amount of 100 parts by weight of the alkali-soluble resin (A), the usage amount of the first alkali-soluble resin (A-1) is 3 parts by weight to 100 parts by weight.

In an embodiment of the invention, based on a usage amount of 100 parts by weight of the alkali-soluble resin (A), the usage amount of the photoacid generator (F) is 0.5 parts by weight to 5 parts by weight.

The invention also provides a production method of a spacer. A spacer having a pattern is obtained by applying a pre-bake treatment, an exposure treatment, a developing treatment, and a post-bake treatment in order on the negative photosensitive resin composition.

The invention also provides a production method of a protective film. A protective film having a pattern is obtained by applying a pre-bake treatment, an exposure treatment, a developing treatment, and a post-bake treatment in order on the negative photosensitive resin composition.

The invention further provides a liquid crystal display device including the spacer obtained by the production method of a spacer.

The invention further provides a liquid crystal display device including the protective film obtained by the production method of a protective film.

Based on the above, the negative photosensitive resin composition of the invention contains a silicone compound (E) of the structure represented by formula (E-1), and therefore the issue of poor sputtering resistance of the spacer or a protective film formed by the negative photosensitive resin composition can be solved.

In order to make the aforementioned features and advantages of the invention more comprehensible, embodiments are described in detail below.

### DESCRIPTION OF THE EMBODIMENTS

<Negative Photosensitive Resin Composition>

The invention provides a photosensitive resin composition containing an alkali-soluble resin (A), a compound (B) containing an ethylenically-unsaturated group, a photoinitiator (C), a solvent (D), and a silicone compound (E) containing the structure represented by formula (E-1). Moreover, the negative photosensitive resin composition of the invention can further contain a photoacid generator (F) and an additive (G).

In the following, the individual components used in the negative photosensitive resin composition of the invention are described in detail.

It should be mentioned that, in the following, (meth)acrylic acid represents acrylic acid and/or methacrylic acid, and (meth)acrylate represents acrylate and/or methacrylate. Similarly, (meth)acryloyl group represents acryloyl group and/or methacryloyl group.

### Alkali-Soluble Resin (A)

The alkali-soluble resin (A) includes a first alkali-soluble resin (A-1) and other alkali-soluble resins (A-2).

### First Alkali-Soluble Resin (A-1)

The first alkali-soluble resin (A-1) is obtained via the polymerization of a monomer mixture. The monomer mixture includes a monomer (a1-I) represented by formula (A1-2), an ethylenically-unsaturated monomer (a1-II) having one or more than one carboxylic acid groups, and other copolymerizable ethylenically-unsaturated monomers (a1-III). Therefore, the first alkali-soluble resin (A-1) has a repeating unit represented by formula (A1-1):

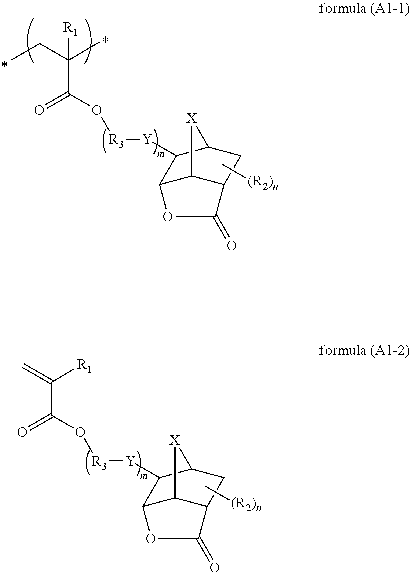

In formula (A1-1) and formula (A1-2), R₁ represents a hydrogen atom or an alkyl group; R₂ represents an alkyl group, a cycloalkyl group, an alkoxy group, an alkoxycarbonyl group, a carboxyl group, a halogen atom, a hydroxyl group, or a cyano group; R₃ represents an alkylene group, a cycloalkylene group, or a combination thereof, and when formula (A1-1) or formula (A1-2) has 2 or more R₃, each R₃ can be the same or different. Y represents a single bond, —O—, —COO—, —CONH—, —NHCOO—, or —NHCONH—, when formula (A1-1) or formula (A1-2) has 2 or more Y, each Y can be the same or different; X represents methylene, methyl methylene, dimethyl methylene, ethylene, —O—, or —S—. m and n each independently represent an integer of 0 to 4, when n is 2 or more, an n number of R₂ can be the same or different; * represents a bonding site.

The weight-average molecular weight of the first alkali-soluble resin (A-1) of the invention only needs to be suitably set based on the object and application, and is generally 2,000 to 50,000, preferably 3,000 to 40,000, and more preferably 4,000 to 30,000.

Monomer (a1-I) Represented by Formula (A1-2)

The monomer (a1-I) represented by formula (A1-2) is shown below, and the monomer (a1-I) represented by formula (A1-2) can form the repeating unit represented by formula (A1-1) via a polymerization reaction:

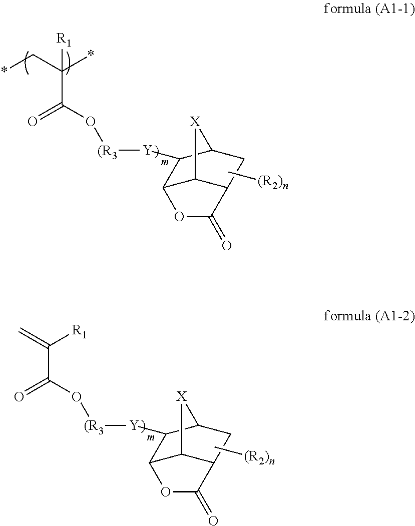

In formula (A1-1) and formula (A1-2), R₁ represents a hydrogen atom or an alkyl group; R₂ represents an alkyl group, a cycloalkyl group, an alkoxy group, an alkoxycarbonyl group, a carboxyl group, a halogen atom, a hydroxyl group, or a cyano group; R₃ represents an alkylene group, a cycloalkylene group, or a combination thereof, and when formula (A1-1) or formula (A1-2) has 2 or more R₃, each R₃ can be the same or different. Y represents a single bond, —O—, —COO—, —CONH—, —NHCOO—, or —NHCONH—, when formula (A1-1) or formula (A1-2) has 2 or more Y, each Y can be the same or different; X represents methylene, methyl methylene, dimethyl methylene, ethylene, —O—, or —S—. m and n each independently represent an integer of 0 to 4, when n is 2 or more, an n number of R₂ can be the same or different; * represents a bonding site.

Specific examples of the monomer (a1-I) represented by formula (A1-2) are provided below, but the invention is not limited thereto.

In the following specific examples, R represents a hydrogen atom, an alkyl group having a substituent, and preferably represents a hydrogen atom, a methyl group, a hydroxymethyl group, or a methyl acetyloxy group.

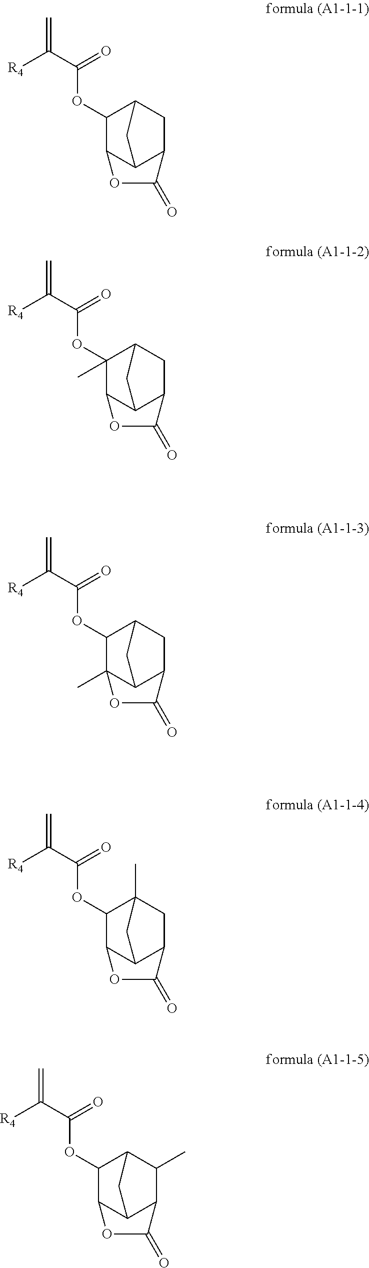

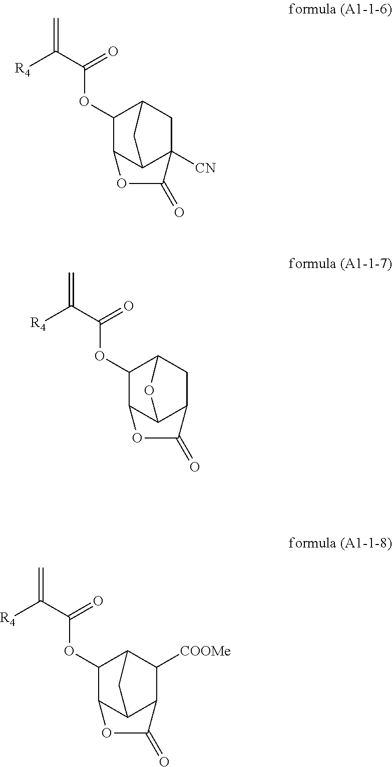

(R₄ represents a hydrogen atom, a methyl group, a hydroxymethyl group, or a perfluoromethyl group.)

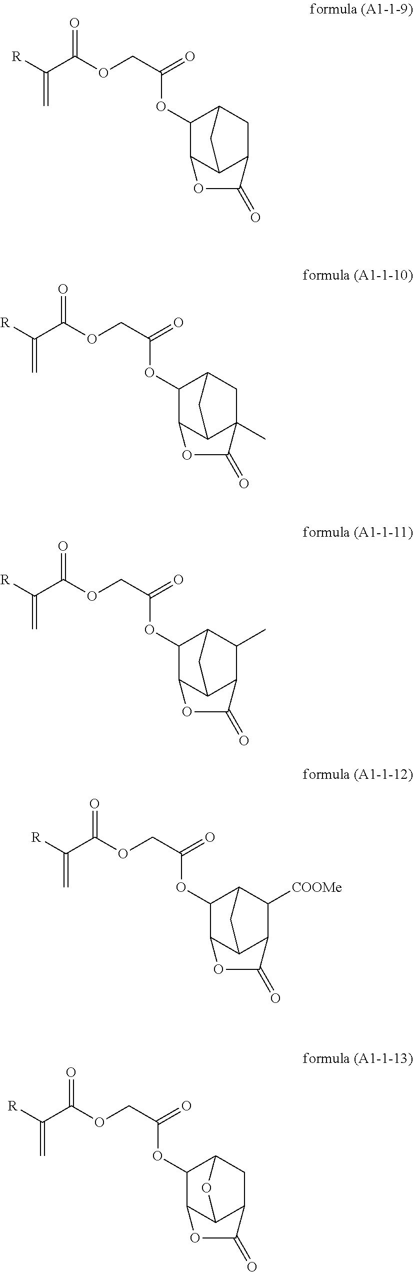

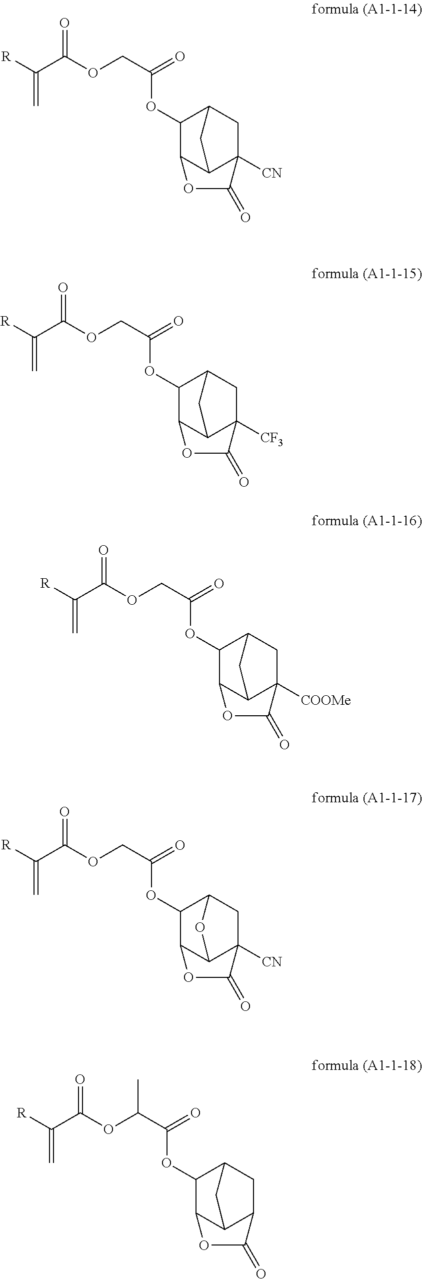

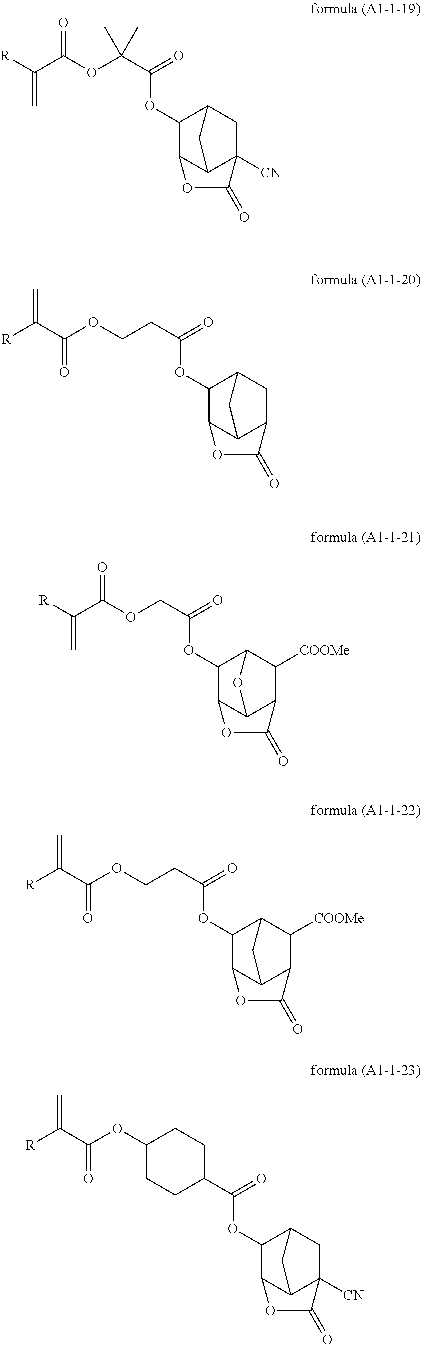

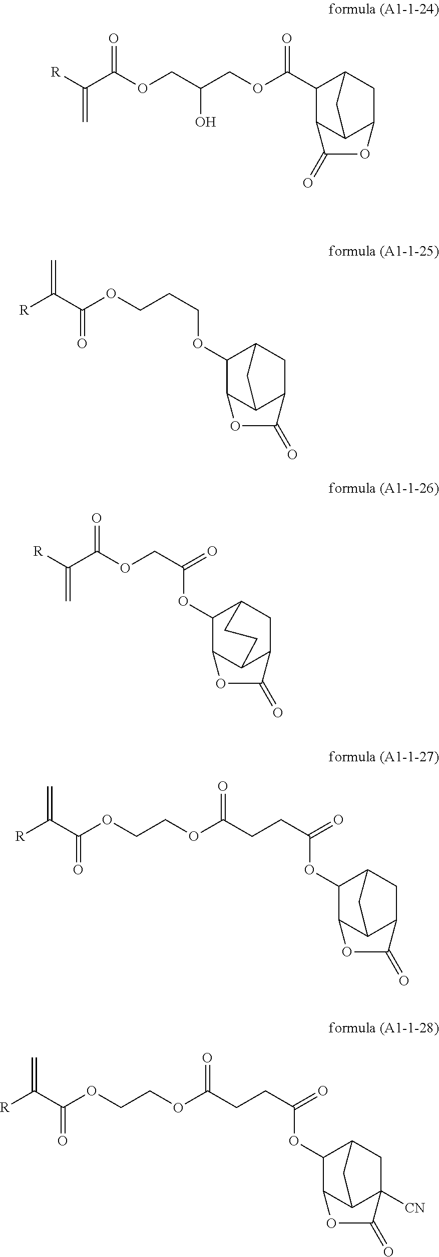

Ethylenically-Unsaturated Monomer (a1-II) Having One or More than One Carboxylic Acid Group

The ethylenically-unsaturated monomer (a1-II) having one or more than one carboxylic acid group can contain, but is not limited to, an unsaturated monocarboxylic acid monomer, an unsaturated polycarboxylic acid monomer, a polycyclic monomer having an unsaturated group and one carboxylic acid group, or a polycyclic monomer having an unsaturated group and a plurality of carboxylic acid groups.

The unsaturated monocarboxylic acid monomer can contain, but is not limited to, for instance, (meth)acrylic acid, butenoic acid, α-chloroacrylic acid, ethyl acrylic acid, cinnamic acid, 2-methacryloyloxyethyl succinate monoester, 2-methacryloyloxyethyl hexahydro terephthalate, 2-methacryloyloxyethyl terephthalate, or omega-carboxypolycaprolactone polyol monoacrylate. The omega-carboxypolycaprolactone polyol monoacrylate can be a product made by Toagosei, model ARONIX M-5300.

The unsaturated polycarboxylic acid monomer can contain, but is not limited to, for instance, maleic acid, fumaric acid, methyl fumaric acid, itaconic acid, or citraconic acid.

The polycyclic monomer having an unsaturated group and one carboxylic acid group can contain, but is not limited to, for instance, 5-carboxybicyclo[2.2.1]hept-2-ene, 5-carboxy-5-methylbicyclo[2.2.1]hept-2-ene, 5-carboxy-5-ethylbicyclo[2.2.1]hept-2-ene, 5-carboxy-6-methylbicyclo[2.2.1]hept-2-ene, or 5-carboxy-6-ethylbicyclo[2.2.1]hept-2-ene.

The polycyclic monomer having an unsaturated group and a plurality of carboxy groups can include, for instance, 5,6-dicarboxy bicyclo [2.2.1]hept-2-ene.

The unsaturated carboxylic acid monomer can be used alone or in multiple combinations.

Preferably, the unsaturated carboxylic acid monomer is selected from acrylic acid, methacrylic acid, 2-methacryloyloxyethyl succinate monoester, 2-methacryloyloxyethyl hexahydro terephthalate, or any combination of the monomers.

The unsaturated carboxylic anhydride monomer can contain, but is not limited to, an unsaturated carboxylic anhydride monomer or a polycyclic monomer having an unsaturated group and a carboxylic anhydride.

The unsaturated carboxylic anhydride monomer can contain, but is not limited to, for instance, maleic anhydride, fumaric anhydride, methyl fumaric anhydride, itaconic anhydride, or citraconic anhydride. The polycyclic monomer having an unsaturated group and a plurality of carboxylic anhydrides can contain, but is not limited to, for instance, 5,6-dicarboxylic anhydride bicyclo[2.2.1]hept-2-ene.

The unsaturated carboxylic anhydride monomer can be used alone or in multiple combinations.

Preferably, the unsaturated carboxylic anhydride monomer is maleic anhydride, fumaric anhydride, methyl fumaric anhydride.

Other Copolymerizable Ethylenically-Unsaturated Monomers (a1-III)

The other copolymerizable ethylenically-unsaturated monomers (a1-III) can contain, but are not limited to, alkyl (meth)acrylate, alicyclic (meth)acrylate, aryl (meth)acrylate, unsaturated dicarboxylate, hydroxyalkyl (meth)acrylate, polyether having a (meth)acrylate group, a styrene monomer, or an unsaturated monomer other than the monomers.

The alkyl (meth)acrylate can contain, but is not limited to, for instance, methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, or tert-butyl (meth)acrylate.

The alicyclic (meth)acrylate can contain, but is not limited to, for instance, cyclohexyl (meth)acrylate, 2-methyl cyclohexyl (meth)acrylate, biscyclopentyl (meth)acrylate (or tricyclo[5.2.1.0^{2,6}]dec-8-yl(meth)acrylate), dicyclopentyloxy ethyl (meth)acrylate, isobornyl (meth)acrylate, or tetrahydrofurfuryl (meth)acrylate.

The aryl (meth)acrylate can contain, but is not limited to, for instance, phenyl (meth)acrylate or benzyl methacrylate.

The unsaturated dicarboxylate can contain, but is not limited to, for instance, diethyl maleate, diethyl fumarate, or diethyl itaconate.

The hydroxyalkyl (meth)acrylate can contain, but is not limited to, for instance, 2-hydroxyethyl (meth)acrylate or 2-hydroxybutyl (meth)acrylate.

The polyether having a (meth)acrylate group can contain, but is not limited to, for instance, polyethylene glycol mono(meth)acrylate or polypropylene glycol mono(meth)acrylate.

The styrene monomer can contain, but is not limited to, for instance, styrene, α-methylstyrene, m-methylstyrene, p-methylstyrene, or p-methoxystyrene.

The unsaturated monomer other than the above monomers can contain, but are not limited to, for instance, acrylonitrile, methacrylonitrile, vinyl chloride, vinylidene chloride, acrylamide, methyl acrylamide, vinyl acetate, 1,3-butadiene, isoprene, 2,3-dimethyl-1,3-butadiene, N-cyclohexylmaleimide, N-phenylmaleimide, N-benzyl maleimide, N-succinimidyl-3-maleimide benzoate, N-succinimidyl-4-maleimide butyrate, N-succinimidyl-6-maleimide hexanoate, N-succinimidyl-3-maleimide propionate, or N-(9-acridinyl)maleimide.

The other copolymerizable ethylenically-unsaturated monomers (a1-III) can be used alone or in multiple combinations.

Preferably, the other copolymerizable ethylenically-unsaturated monomers (a1-III) are selected from methyl (meth)acrylate, butyl (meth)acrylate, 2-hydroxyethyl (meth)acrylate, tert-butyl (meth)acrylate, phenylmethyl (meth)acrylate, biscyclopentyl (meth)acrylate, isobornyl methacrylate, dicyclopentyloxy ethyl (meth)acrylate, styrene, p-methoxystyrene, or any combination of the monomers.

In the first alkali-soluble resin (A-1), based on a total amount of 100 parts by weight of the monomer mixture, the usage amount of the monomer represented by formula (A1-2) is 3 parts by weight to 30 parts by weight, preferably 4 parts by weight to 28 parts by weight, more preferably 5 parts by weight to 25 parts by weight, and the monomer mixture includes the monomer (a1-I) represented by formula (A1-2), the ethylenically-unsaturated monomer (a1-II) having one or more than one carboxylic acid group, and other copolymerizable ethylenically-unsaturated monomers (a1-III). When the first alkali-soluble resin (A-1) has a repeating unit represented by formula (A1-1), the sputtering resistance of the spacer or a protective film formed by the negative photosensitive resin composition can be further increased.

The polymerization method can be suitably selected according to the object or application, and can include, for instance, a known polymerization method such as bulk polymerization, solution polymerization, emulsion polymerization, and is preferably solution polymerization. Structures thereof such as molecular weight are readily adjusted, and therefore the composition is beneficial for industrial use. Moreover, the polymerization mechanism includes a known polymerization method such as using a radical polymerization initiator, an anionic polymerization initiator, a cationic polymerization initiator, a coordination polymerization initiator.

The polymerization method of the monomer component can include a known method, including the use of an energy source such as self-heating, electromagnetic wave (infrared, UV, X-ray . . . etc.), or electron beam to provide the energy needed for polymerization to the monomer component. Preferably, a polymerization initiator is also used, such that the energy needed for the polymerization can be reduced and the reaction is more readily controlled.

The method of controlling the molecular weight can include, for instance, a known method of controlling, for instance, the polymerization initiator, the polymerization temperature, the chain-transfer agent.

When the monomer adopts a solution polymerization method, the solvent used in the polymerization is not particularly limited as long as it is suitably set according to polymerization conditions such as the type or the amount, the polymerization temperature, the polymerization concentration of the monomer used.

Specific examples of the solvent can contain, but are not limited to, monool such as methanol, ethanol, isopropanol, n-butanol, 2-butanol; alcohol such as glycol, propanediol; cyclic ether such as tetrahydrofuran, dioxane; ethylene glycol monoether such as ethylene glycol monomethyl ether, ethylene glycol monoethyl ether, ethylene glycol monobutyl ether, diethylene glycol monomethyl ether, diethylene glycol monoethyl ether, diethylene glycol monobutyl ether, propylene glycol monomethyl ether, propylene glycol monoethyl ether, propylene glycol monobutyl ether, 3-methoxy butanol; ethylene glycol diether such as ethylene glycol dimethyl ether, ethylene glycol diethyl ether, ethylene glycol ethyl methyl ether, diethylene glycol dimethyl ether, diethylene glycol diethyl ether, diethylene glycol ethyl methyl ether, propylene glycol dimethyl ether, propylene glycol diethyl ether; ethylene glycol monoether ester such as ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, 3-methoxybutyl acetate; alkyl ester such as methyl acetate, ethyl acetate, propyl acetate, isopropyl, butyl acetate, methyl propionate, ethyl propionate, butyl propionate, methyl lactate, ethyl lactate, butyl lactate, methyl 3-methoxypropionate, ethyl 3-methoxypropionate, methyl 3-ethoxypropionate, ethyl 3-ethoxypropionate, methyl acetoacetate, ethyl acetoacetate; ketone such as acetone, methyl ethyl ketone, methyl isobutyl ketone, cyclohexanone; aromatic hydrocarbon such as benzene, toluene, xylene, ethylbenzene; aliphatic hydrocarbon such as n-hexane, cyclohexane, octane; amide such as dimethylformamide, dimethylacetamide, N-methylpyrrolidone. The solvent can be used alone or in multiple combinations.

The radical polymerization initiator is not particularly limited as long as it can provide thermal energy to generate a radical, wherein a polymerization initiator generating a radical via heat is more beneficial for industrial use.

Specific examples of the radical polymerization initiator can contain, but are not limited to, for instance, cumene hydroperoxide, diisopropylbenzene hydroperoxide, 2-tert-butyl hydroperoxide, lauroyl peroxide, benzoyl peroxide, tert-butyl peroxy isopropyl carbonate, tert-butylperoxy-2-ethyl hexanoate, azobisisobutyronitrile, 1,1′-azobis(cyclohexanecarbonitrile), 2,2′-azobis(2,4-dimethylvaleronitrile), 2,2′-azobis(2-methylpropionate), hydrogen peroxide, persulfate. The radical polymerization initiator can be used alone or in multiple combinations. At the same time, the radical polymerization initiator can be used with a transition metal salt or an amine.

The amount of the radical polymerization initiator is not particularly limited as long as it is suitably set according to polymerization conditions such as the type or the amount, the polymerization temperature, the polymerization concentration of the monomer used.

In the polymerization process, when needed, a chain-transfer agent can also be used, wherein when a chain-transfer agent is used, the molecular weight distribution of the polymer in the reaction tends to be inhibited to prevent gelation of the polymer. Specific examples of the chain-transfer agent can contain, but are not limited to, mercapto carboxylic acid such as thioglycolic acid, 3-mercaptopropionic acid; mercaptocarboxylic ester such as methyl thioglycolate, methyl 3-mercaptopropionate, 2-ethylhexyl 3-mercaptopropionate, n-octyl 3-mercaptopropionate, methoxybutyl 3-mercaptopropionate, stearyl 3-mercaptopropionate, trimethylolpropane tris(3-mercaptopropionate), pentaerythritol tetrakis(3-mercaptopropionate), dipentaerythritol hexa(3-mercaptopropionate); alkylthiol such as ethyl mercaptan, tert-butyl mercaptan, n-dodecyl mercaptan, 1,2-dimercaptoethane; mercapto alcohol such as 2-mercaptoethanol, 4-mercapto-1-butanol; aromatic thiol such as benzenethiol, m-toluene thiol, p-toluene thiol, 2-naphthalenethiol; mercapto isocyanurate such as tris[(3-mercaptopropionate acyloxy)-ethyl]isocyanurate.

The chain-transfer agent can also adopt a chain-transfer agent other than a compound having a sulfur group such as disulfide such as 2-hydroxyethyl disulfide, tetraethyl thiuram disulfide; dithiocarbamate such as diethyl dibenzyl; monomer dimer such as α-methylstyrene dimer; haloalkyl such as carbon tetrabromide. In terms of obtainability, anti-crosslinking ability, smaller degree of reducing polymerization rate, the chain-transfer agent is preferably a compound having a mercapto group such as mercapto carboxylic acid, mercaptocarboxylic ester, alkylthiol, mercapto alcohol, aromatic thiol, mercapto isocyanurate. The chain-transfer agent can be used alone or in multiple combinations.

The amount of the chain-transfer agent is not particularly limited as long as it is suitably set according to polymerization conditions such as the type or the amount, the polymerization temperature, the polymerization concentration of the monomer used.

The temperature of the polymerization reaction only needs to be suitably set according to polymerization conditions such as the type or the amount and the polymerization initiator of the monomer used, and is preferably 50° C. to 200° C., more preferably 70° C. to 150° C.

Ethylenically-Unsaturated Monomer (a1-IV) Having an Epoxy Group

In another specific example of the invention, the first alkali-soluble resin (A-1) can be obtained by performing an open-ring reaction on a copolymer obtained by copolymerizing the monomer (a1-I) represented by formula (A1-2), the ethylenically-unsaturated monomer (a1-II) having one or more than one carboxylic acid group, and the other copolymerizable ethylenically-unsaturated monomers (a1-III) with the ethylenically-unsaturated monomer (a1-IV) having an epoxy group.

The ethylenically-unsaturated monomer (a1-IV) having an epoxy group can contain, but is not limited to, for instance, a (meth)acrylate monomer having an epoxy group, an α-alkyl acrylate compound having an epoxy group, or an epoxypropyl ether monomer.

The (meth)acrylate monomer having an epoxy group can contain, but is not limited to, for instance, glycidyl (meth)acrylate, 2-methyl glycidyl (meth)acrylate, 3,4-epoxybutyl (meth)acrylate, 6,7-epoxyheptyl (meth)acrylate, 3,4-epoxycyclohexyl (meth)acrylate, or 3,4-epoxycyclohexylmethyl (meth)acrylate.

The α-alkyl acrylate monomer having an epoxy group can contain, but is not limited to, for instance, α-ethyl glycidyl acrylate, α-n-propyl glycidyl acrylate, α-n-butyl glycidyl acrylate, or 6,7-epoxyheptyl-α-ethyl acrylate.

The epoxypropyl ether monomer can contain, but is not limited to, for instance, o-vinylbenzylglycidylether, m-vinyl benzylglycidylether, or p-vinylbenzyl glycidylether.

The ethylenically-unsaturated monomer (a1-IV) having an epoxy group can be used alone or in multiple combinations.

Preferably, the ethylenically-unsaturated monomer (a1-IV) having an epoxy group is selected from glycidyl methacrylate, 3,4-epoxycyclohexylmethyl methacrylate, 6,7-epoxyheptyl methacrylate, o-vinylbenzylglycidylether, m-vinylbenzylglycidylether, p-vinylbenzylglycidylether, or any combination of the monomers.

When the first alkali-soluble resin (A-1) is obtained by performing an open-ring reaction on a copolymer obtained by copolymerizing the monomer (a1-I) represented by formula (A1-2), the ethylenically-unsaturated monomer (a1-II) having one or more than one carboxylic acid group, and the other copolymerizable ethylenically-unsaturated monomers (a1-III) with the ethylenically-unsaturated monomer (a1-IV) having an epoxy group, the first alkali-soluble resin (A-1) has an ethylenically-unsaturated group, and the sputtering resistance of the spacer or a protective film formed by the negative photosensitive resin composition can be increased. For instance, as shown by the following formula, an open-ring reaction is performed on glycidyl methacrylate and the methacrylic acid repeating unit in the first alkali-soluble resin, such that the first alkali-soluble resin (A-1) has an ethylenically-unsaturated group.

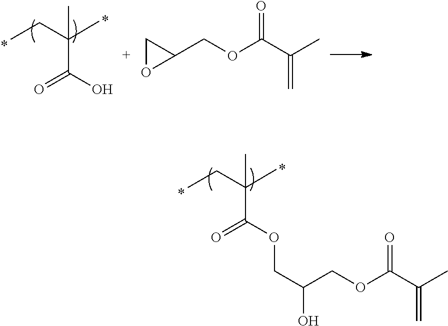

Based on a usage amount of 100 parts by weight of the alkali-soluble resin (A), the usage amount of the first alkali-soluble resin (A-1) can be 3 parts by weight to 100 parts by weight, preferably 10 parts by weight to 100 parts by weight, and more preferably 20 parts by weight to 100 parts by weight.

When the negative photosensitive resin composition contains the first alkali-soluble resin (A-1), the sputtering resistance of the spacer or a protective film formed by the negative photosensitive resin composition can be further increased.

### Other Alkali-Soluble Resins (A-2)

The alkali-soluble resin (A) of invention can further contain other alkali-soluble resins (A-2), and the other alkali-soluble resins (A-2) are obtained from the copolymerization of an ethylenically-unsaturated monomer containing one or more than one carboxylic acid group and other copolymerizable ethylenically-unsaturated monomers. Based on 100 parts by weight of the total usage amount of the monomer for copolymerization, preferably, the other alkali-soluble resins (A-2) are obtained from the copolymerization of 5 parts by weight to 50 parts by weight of an ethylenically-unsaturated monomer containing one or more than one carboxylic acid group and 50 parts by weight to 95 parts by weight of other copolymerizable ethylenically-unsaturated monomers.

The ethylenically-unsaturated monomer containing one or more than one carboxylic acid groups can be used alone or in combination, and the ethylenically-unsaturated monomer containing a carboxylic acid group contains, but is not limited to, unsaturated monocarboxylic acid such as acrylic acid, methacrylic acid (MAA), butenoic acid, α-chloroacrylic acid, ethyl acrylic acid, cinnamic acid, 2-acryloylethoxy succinate, or 2-methacryloyloxyethyl succinate monoester (HOMS); an unsaturated dicarboxylic acid (anhydride) such as maleic acid, maleic anhydride, fumaric acid, itaconic acid, itaconic anhydride, citraconic acid, and citraconic anhydride; an unsaturated polycarboxylic acid (anhydride) of at least three carboxylic acid groups. Preferably, the ethylenically-unsaturated monomer containing a carboxylic acid group is selected from acrylic acid, methacrylic acid, 2-acryloylethoxy succinate, or 2-methacryloyloxyethyl succinate. More preferably, the ethylenically-unsaturated monomer containing a carboxylic acid group is selected from 2-acryloylethoxy succinate or 2-methacryloyloxyethyl succinate, so that pigment dispersion can be increased, developing speed can be increased, and the generation of residue is reduced.

The other copolymerizable ethylenically-unsaturated monomers can be used alone or in combination, and the other copolymerizable ethylenically-unsaturated monomers contain, but are not limited to, an aromatic vinyl compound such as styrene (SM), α-methylstyrene, vinyltoluene, p-chlorostyrene, methoxystyrene; maleimide such as N-phenylmaleimide (PMI), N-o-hydroxyphenyl maleimide, N-m-hydroxyphenyl maleimide, N-p-hydroxyphenyl maleimide, N-o-methylphenyl maleimide, N-m-methylphenyl maleimide, N-p-methylphenyl maleimide, N-o-methoxyphenyl maleimide, N-m-methoxyphenyl maleimide, N-p-methoxyphenyl maleimide, N-cyclohexylmaleimide; unsaturated carboxylate such as methyl acrylate (MA), methyl methacrylate, ethyl acrylate, ethyl methacrylate, n-propyl acrylate, n-propyl methacrylate, iso-propyl acrylate, iso-propyl methacrylate, n-butyl acrylate, n-butyl methacrylate, iso-butyl acrylate, iso-butyl methacrylate, sec-butyl acrylate, sec-butyl methacrylate, tert-butyl acrylate, tert-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate (BzMA), phenyl acrylate, phenyl methacrylate, methoxy triethylene glycol acrylate, methoxy triethylene glycol methacrylate, lauryl methacrylate, tetradecyl methacrylate, hexadecyl methacrylate, octadecyl methacrylate, eicosyl methacrylate, docosyl methacrylate, or dicyclopentenyloxyethyl acrylate (DCPOA); N,N-dimethyl aminoethyl acrylate, N,N-dimethyl aminoethyl methacrylate, N,N-diethyl aminopropyl acrylate, N,N-dimethyl aminopropyl methacrylate, N,N-dibutyl aminopropyl acrylate, or N-methacrylate iso-butyl amino ethyl; unsaturated epoxypropyl carboxylate such as epoxypropyl acrylate and epoxypropyl methacrylate; vinyl carboxylate such as vinyl acetate, vinyl propionate, vinyl butyrate; unsaturated ether such as methyl vinyl ether, ethyl vinyl ether, allyl glycidyl ether, methallyl glycidyl ether; a vinyl cyanide compound such as acrylonitrile, methacrylonitrile, α-chloroacrylonitrile, vinylidene cyanide; unsaturated amide such as acrylamide, methacrylamide, α-chloro acrylamide, N-hydroxyethyl acrylamide, and N-hydroxyethyl methacrylamide; aliphatic conjugated diene such as 1,3-butadiene, isoamylene, chlorobutadiene.

Preferably, the other copolymerizable ethylenically-unsaturated monomers are selected from styrene, N-phenylmaleimide, methyl acrylate, methyl methacrylate, 2-hydroxyethyl acrylate, 2-hydroxyethyl methacrylate, benzyl acrylate, benzyl methacrylate, dicyclopentenyloxyethyl acrylate, or a combination thereof.

When preparing the other alkali-soluble resins (A-2), a solvent can be used, wherein the solvent can be used alone or in combination, and the solvent contains, but is not limited to, for instance, (poly)alkylene glycol monoalkyl ether such as ethylene glycol monomethyl ether, ethylene glycol monoethyl ether, diethylene glycol monomethyl ether, diethylene glycol monoethyl ether, diethylene glycol n-propyl ether, diethylene glycol n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol n-propyl ether, dipropylene glycol n-butyl ether, tripropylene glycol monomethyl ether, tripropylene glycol monoethyl ether; (poly)alkylene glycol monoalkyl ether acetate such as ethylene glycol monomethyl ether acetate, ethylene glycol monoethyl ether acetate, propylene glycol monomethyl ether acetate (PGMEA), propylene glycol monoethyl ether acetate; other ethers such as diethylene glycol dimethyl ether, diethylene glycol methyl ethyl ether, diethylene glycol diethyl ether, tetrahydrofuran; ketone such as methyl ethyl ketone, cyclohexanone, 2-heptanone, 3-heptanone; alkyl lactate such as methyl 2-hydroxypropanoate, ethyl 2-hydroxypropanoate; other esters such as methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate (EEP), ethyl ethoxyacetate, ethyl hydroxyacetate, methyl 2-hydroxy-3-methylbutanoate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-methoxybutyrate; aromatic hydrocarbon such as toluene, xylene; amine such as N-methylpyrrolidone (NMP), N,N-dimethylformamide (DMF), or N,N-dimethylacetamide (DMAC). Preferably, the solvent is selected from PGMEA, EEP, or a combination thereof. The (poly)alkylene glycol monoalkyl ether refers to alkylene glycol monoalkyl ether or polyalkylene glycol monoalkyl ether. The (poly)alkylene glycol monoalkyl ether acetate refers to alkylene glycol monoalkyl ether acetate or polyalkylene glycol monoalkyl ether acetate.

The initiator used in the preparation of the other alkali-soluble resins (A-2) is generally a radical polymerization initiator, and specific examples include, for instance: an azo compound such as 2,2′-azobisisobutyronitrile, 2,2′-azobis(2,4-dimethyl valeronitrile), 2,2′-azobis(4-methoxy-2,4-dimethylvaleronitrile), 2,2′-azobis-2-methyl butyronitrile (AMBN); and a peroxy compound such as benzoyl peroxide.

Based on a usage amount of 100 parts by weight of the alkali-soluble resin (A), the usage amount of the other alkali-soluble resins (A-1) is 0 parts by weight to 100 parts by weight, preferably 0 parts by weight to 90 parts by weight, and more preferably 0 parts by weight to 80 parts by weight.

The weight-average molecular weight of the other alkali-soluble resins (A-2) of the invention only needs to be suitably set based on the object and application, and is generally 2,000 to 50,000, preferably 3,000 to 40,000, and more preferably 4,000 to 30,000.

### Compound (B) Containing an Ethylenically-Unsaturated Group

The compound (B) containing an ethylenically-unsaturated group can be selected from a compound (B-1) having 1 ethylenically-unsaturated group or a compound (B-2) having 2 or more ethylenically-unsaturated groups.

### Compound (B-1) Having 1 Ethylenically-Unsaturated Group

The compound (B-1) having 1 ethylenically-unsaturated group can contain, but is not limited to, for instance, (meth)acrylamide, (meth)acryloylmorpholine, 7-amino-3,7-dimethyloctyl(meth)acrylate, isobutoxymethyl(meth)acrylamide, isobornyl oxyethyl(meth)acrylate, isobornyl(meth)acrylate, 2-ethylhexyl(meth)acrylate, ethyl diethylene glycol(meth)acrylate, tert-octyl(meth)acrylamide, diacetone(meth)acrylamide, dimethylaminoethyl(meth)acrylate, dodecyl (meth)acrylate, dicyclopentenyl oxyethyl(meth)acrylate, dicyclopentenyl(meth)acrylate, N,N-dimethyl(meth)acrylamide, tetrachlorophenyl(meth)acrylate, 2-tetrachlorophenoxy ethyl(meth)acrylate, tetrahydrofurfuryl(meth)acrylate, tetrabromophenyl(meth)acrylate, 2-tetrabromo phenoxyethyl(meth)acrylate, 2-trichlorophenoxyethyl(meth)acrylate, tribromo phenyl(meth)acrylate, 2-tribromophenoxyethyl(meth)acrylate, 2-hydroxy-ethyl (meth)acrylate, 2-hydroxy-propyl(meth)acrylate, vinylcaprolactam, N-vinylpyrrolidone, phenoxyethyl (meth)acrylate, pentachlorophenyl(meth)acrylate, pentabromophenyl (meth)acrylate, polyethylene glycol mono(meth)acrylate, polypropylene glycol mono(meth)acrylate, bornyl (meth)acrylate. The compound (B-1) having 1 ethylenically-unsaturated group generally can be used alone or in multiple combinations.

### Compound (B-2) Having 2 or More Ethylenically-Unsaturated Groups

The compound (B-2) having 2 or more ethylenically-unsaturated groups contains, but is not limited to, for instance, ethylene glycol di(meth)acrylate, dicyclopentenyl di(meth)acrylate, triethylene glycol di(meth)acrylate, tetraethylene glycol di(meth)acrylate, tri(2-hydroxyethyl)isocyanate di(meth)acrylate, tri(2-hydroxyethyl) isocyanate tri(meth)acrylate, caprolactone-modified tri(2-hydroxyethyl)isocyanate tri(meth)acrylate, trimethylolpropyl tri(meth)acrylate, ethylene oxide (EO)-modified trimethylolpropyl tri(meth)acrylate, propylene oxide (PO)-modified trimethylolpropyl tri(meth)acrylate, tripropylene glycol di(meth)acrylate, neo-pentyl glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, di(trimethylolpropane) tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, PO-modified glycerol tri(meth)acrylate, EO-modified bisphenol F di(meth)acrylate, novolac polyglycidyl ether (meth)acrylate. The compound (B-2) having 2 or more ethylenically-unsaturated groups generally can be used alone or in multiple combinations.

Specific examples of the compound (B) containing an ethylenically-unsaturated group include trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, caprolactone-modified dipentaerythritol hexaacrylate, di(trimethylolpropyl)tetraacrylate, PO-modified glycerol triacrylate, or any combination of the above.

Based on 100 parts by weight of the usage amount of the alkali-soluble resin (A), the usage amount of the compound (B) containing an ethylenically-unsaturated group is 30 parts by weight to 300 parts by weight, preferably 50 parts by weight to 280 parts by weight, more preferably 70 parts by weight to 250 parts by weight.

### Photoinitiator (C)

The photoinitiator (C) is not particularly limited, and in an embodiment of the invention, can contain, but is not limited to, for instance, an O-acyloxime compound, a triazine compound, a acetophenone compound, a biimidazole compound, a benzophenone compound, an α-diketone compound, a ketol compound, an ether ketone compound, an acylphosphine oxide compound, a quinone compound, a halogen-containing compound, peroxide, which are respectively described below.

Specific examples of the O-oxime compound include 1-[4-(phenylthio)phenyl]-heptane-1,2-dione 2-(O-benzoyloxime), 1-[4-(phenylthio) phenyl]-octane-1,2-dione 2-(O-benzoyloxime), 1-[4-(benzoyl)phenyl]-octane-1,2-dione 2-(O-benzoyloxime), 1-[9-ethyl-6-(2-methylbenzoyl)-9H-carbazol-3-yl]-ethanone 1-(O-acetyloxime), 1-[9-ethyl-6-(3-methylbenzoyl)-9H-carbazol-3-yl]-ethanone 1-(O-acetyloxime), 1-[9-ethyl-6-benzoyl-9H-carbazol-3-yl]-ethanone 1-(O-acetyloxime), ethanone-1-[9-ethyl-6-(2-methyl-4-tetrahydrofuranbenzoyl)-9H-carbazol-3-yl]-1-(O-acetyloxime), ethanone-1-[9-ethyl-6-(2-methyl-5-tetrahydropyranylbenzoyl)-9H-carbazol-3-yl]-1-(O-acetyloxime), ethanone-1-[9-ethyl-6-(2-methyl-5-tetrahydrofuranbenzoyl)-9H-carbazol-3-yl]-1-(O-acetyloxime), ethanone-1-[9-ethyl-6-(2-methyl-4-tetrahydrofuranmethoxybenzoyl)-9H-carbazol-3-yl]-1-(O-acetyloxime), ethanone-1-[9-ethyl-6-(2-methyl-4-tetrahydropyranylmethoxybenzoyl)-9H-carbazol-3-yl]-1-(O-acetyloxime), ethanone-1-[9-ethyl-6-(2-methyl-5-tetrahydrofuran methoxybenzoyl)-9H-carbazol-3-yl]-1-(O-acetyloxime), ethanone-1-[9-ethyl-6-(2-methyl-5-tetrahydropyranylmethoxybenzoyl)-9H-carbazol-3-yl]-1-(O-acetyloxime), ethanone-1-[9-ethyl-6-{2-methyl-4-(2,2-dimethyl-1,3-dioxolan)benzoyl}-9H-carbazol-3-yl]-1-(O-acetyloxime), or ethanone-1-[9-ethyl-6-{2-methyl-4-(2,2-dimethyl-1,3-dioxolan)methoxy benzoyl}-9H-carbazol-3-yl]-1-(O-acetyloxime).

The O-oxime compound is preferably, for instance, 1-[4-(phenylthio) phenyl]-octane-1,2-dione 2-(O-benzoyloxime) (such as OXE-01 made by Ciba Specialty Chemicals), 1-[9-ethyl-6-(2-methylbenzoyl)-9H-carbazol-3-yl]-ethanone 1-(O-acetyl oxime) (such as OXE-02 made by Ciba Specialty Chemicals), ethanone-1-[9-ethyl-6-(2-methyl-4-tetrahydrofuranmethoxybenzoyl)-9H-carbazol-3-yl]-1-(O-acetyloxime), ethanone-1-[9-ethyl-6-{2-methyl-4-(2,2-dimethyl-1,3-dioxolan)methoxybenzoyl}-9H-carbazol-3-yl]-1-(O-acetyloxime). The O-oxime compound can be used alone or in multiple combinations, which is decided based on actual need.

The triazine compound can include, but is not limited to, for instance, a vinyl group-halogenated methyl-s-triazine compound, a 2-(naphtho-1-yl)-4,6-bis-halogenated methyl-s-triazine compound, and a 4-(p-aminophenyl)-2,6-bi-halogenated methyl-s-triazine compound.

Specific examples of the vinyl group-halogenated methyl-s-triazine compound include, for instance, 2,4-bis(trichloromethyl)-6-p-methoxystyryl-s-triazine, 2,4-bis(trichloromethyl)-3-(1-p-dimethylaminophenyl-1,3-butadienyl)-s-triazine, 2-trichloromethyl-3-amino-6-p-methoxystyryl-s-triazine.

Specific examples of the 2-(naphtho-1-yl)-4,6-bis-halogenated methyl-s-triazine compound include, for instance, 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine, 2-[4-(2-ethoxyethyl)-naphtho-1-yl]-4,6-bis-trichloromethyl-s-triazine, 2-[4-(2-butoxy ethyl)-naphtho-1-yl]-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxynaphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine.

Specific examples of the 4-(p-aminophenyl)-2,6-di-halogenated methyl-s-triazine compound include, for instance, 4-[p-N,N-di (ethoxycarbonylmethyl)aminophenyl]-2,6-di(trichloromethyl)-s-triazine, 4-[o-methyl-p-N,N-di(ethoxycarbonylmethyl)aminophenyl]-2,6-di(trichloromethyl)-s-triazine, 4-[p-N,N-di(chloroethyl)aminophenyl]-2,6-di(trichloromethyl)-s-triazine, 4-[o-methyl-p-N,N-di(chloroethyl)aminophenyl]-2,6-di(trichloromethyl)-s-triazine, 4-(p-N-chloroethylamino phenyl)-2,6-di(trichloromethyl)-s-triazine, 4-(p-N-ethoxycarbonylmethylaminophenyl)-2,6-di(trichloromethyl)-s-triazine, 4-[p-N,N-di(phenyl)aminophenyl]-2,6-di(trichloro methyl)-s-triazine, 4-(p-N-chloroethylcarbonylaminophenyl)-2,6-di(trichloromethyl)-s-triazine, 4-[p-N-(p-methoxyphenyl)carbonylaminophenyl]-2,6-di(trichloromethyl)-s-triazine, 4-[m-N,N-di(ethoxycarbonylmethyl)aminophenyl]-2,6-di(trichloromethyl)-s-triazine, 4-[m-bromo-p-N,N-di(ethoxycarbonylmethyl)aminophenyl]-2,6-di(trichloromethyl)-s-triazine, 4-[m-chloro-p-N,N-di(ethoxycarbonylmethyl)aminophenyl]-2,6-di (trichloromethyl)-s-triazine, 4-[m-fluoro-p-N,N-di(ethoxycarbonylmethyl)aminophenyl]-2,6-di(trichloromethyl)-s-triazine, 4-[o-bromo-p-N,N-di(ethoxycarbonylmethyl)amino phenyl]-2,6-di(trichloromethyl)-s-triazine, 4-[o-chloro-p-N,N-di(ethoxycarbonylmethyl) aminophenyl]-2,6-di(trichloromethyl)-s-triazine, 4-[o-fluoro-p-N,N-di(ethoxycarbonyl methyl)aminophenyl]-2,6-di(trichloromethyl)-s-triazine, 4-[o-bromo-p-N,N-di(chloro ethyl)aminophenyl]-2,6-di(trichloromethyl)-s-triazine, 4-[o-chloro-p-N,N-di(chloroethyl) aminophenyl]-2,6-di(trichloromethyl)-s-triazine, 4-[o-fluoro-p-N,N-di(chloroethyl)amino phenyl]-2,6-di(trichloromethyl)-s-triazine, 4-[m-bromo-p-N,N-di(chloroethyl)amino phenyl]-2,6-di(trichloromethyl)-s-triazine, 4-[m-chloro-p-N,N-di(chloroethyl)amino phenyl]-2,6-di(trichloromethyl)-s-triazine, 4-[m-fluoro-p-N,N-di(chloroethyl)amino phenyl]-2,6-di(trichloromethyl)-s-triazine, 4-(m-bromo-p-N-ethoxycarbonylmethylamino phenyl)-2,6-di(trichloromethyl)-s-triazine, 4-(m-chloro-p-N-ethoxycarbonylmethylamino phenyl)-2,6-di(trichloromethyl)-s-triazine, 4-(m-fluoro-p-N-ethoxycarbonylmethylamino phenyl)-2,6-di(trichloromethyl)-s-triazine, 4-(o-bromo-p-N-ethoxycarbonylmethylamino phenyl)-2,6-di(trichloromethyl)-s-triazine, 4-(o-chloro-p-N-ethoxycarbonylmethylamino phenyl)-2,6-di(trichloromethyl)-s-triazine, 4-(o-fluoro-p-N-ethoxycarbonylmethylamino phenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di (trichloromethyl)-s-triazine, 4-(in-fluoro-p-N-chloroethylaminophenyl)-2,6-di(trichloro methyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, 4-(o-fluoro-p-N-chloroethylaminophenyl)-2,6-di(trichloromethyl)-s-triazine, 2,4-di(trichloromethyl)-6-[3-bromo-4-[N,N-di(ethoxycarbonylmethyl)amino]phenyl]-1, 3,5-triazine.

The triazine compound is preferably 4-[m-bromo-p-N,N-bis(ethoxycarbonyl methyl)aminophenyl]-2,6-bis(trichloromethyl)-s-triazine, 2,4-bis(trichloromethyl)-6-p-methoxystyryl-s-triazine. The triazine compound can be used alone or in multiple combinations, which is decided based on actual need.

Specific examples of the acetophenone compound include, for instance, p-dimethylamino-acetophenone, α,α′-dimethoxyazoxy-acetophenone, 2,2′-dimethyl-2-phenyl-acetophenone, p-methoxy-acetophenone, 2-methyl-1-[4-(methylthio)phenyl]-2-morpholino-1-propanone, 2-benzyl-2-N,N-dimethylamino-1-(4-morpholinophenyl)-1-butanone. The acetophenone compound is preferably 2-methyl-1-[4-(methylthio)phenyl]-2-morpholinyl-1-propanon or 2-benzyl-2-N,N-dimethylamino-1-(4-morpholinophenyl)-1-butanone. The acetophenone compound can be used alone or in multiple combinations, which is decided based on actual need.

Specific examples of the biimidazole compound include, for instance, 2,2′-bis(o-chlorophenyl)-4,4′,5,5′-tetraphenylbiimidazole, 2,2′-bis(o-fluorophenyl)-4,4′,5,5′-tetraphenylbiimidazole, 2,2′-bis(o-methylphenyl)-4,4′,5,5′-tetraphenylbiimidazole, 2,2′-bis(o-methoxyphenyl)-4,4′,5,5′-tetraphenylbiimidazole, 2,2′-bis (o-ethylphenyl)-4,4′,5,5′-tetraphenylbiimidazole, 2,2′-bis(p-methoxyphenyl)-4,4′,5,5′-tetraphenylbiimidazole, 2,2′-bis(2,2′,4,4′-tetramethoxyphenyl)-4,4′,5,5′-tetraphenylbiimidazole, 2,2′-bis(2-chlorophenyl)-4,4′,5,5′-tetraphenylbiimidazole, 2,2′-bis (2,4-dichlorophenyl)-4,4′,5,5′-tetraphenylbiimidazole. The biimidazole compound is preferably 2,2′-bis(2,4-dichlorophenyl)-4,4′,5,5′-tetraphenylbiimidazole. The biimidazole compound can be used alone or in multiple combinations, which is decided based on actual need.

Specific examples of the benzophenone compound include, for instance, thioxanthone, 2,4-diethylthioxanthone, thioxanthone-4-sulfone, benzophenone, 4,4′-bis(dimethylamino)benzophenone, 4,4′-bis(diethylamino)benzophenone. The benzophenone compound is preferably 4,4′-bis(diethylamino)benzophenone. The benzophenone compound can be used alone or in multiple combinations, which is decided based on actual need.

Specific examples of the α-diketone compound include, for instance, benzilic acid and an acetyl group. Specific examples of the ketol compound include benzoin. Specific examples of the ether ketone compound include, for instance, benzoin methyl ether, benzoin ethyl ether, benzoin isopropyl ether. Specific examples of the acylphosphine oxide compound include, for instance, 2,4,6-trimethyl benzoyldiphenylphosphine oxide, bis(2,6-dimethoxybenzoyl)2,4,4-trimethylpentyl phosphine oxide. Specific examples of the quinone compound include, for instance, anthraquinone, 1,4-naphthoquinone. Specific examples of the halogen-containing compound include, for instance, phenacyl chloride, tribromomethyl phenyl sulfone, tris(trichloromethyl)-s-triazine. Specific examples of the peroxide include, for instance, di-tert-butyl peroxide. The α-diketone compound, ketol compound, ether ketone compound, acylphosphine oxide compound, quinone compound, halogen-containing compound, peroxide . . . etc. can be used alone or in multiple combinations, which is decided based on actual need.

Based on a usage amount of 100 parts by weight of the alkali-soluble resin (A), the usage amount of the photoinitiator (C) is 10 parts by weight to 80 parts by weight, preferably 12 parts by weight to 75 parts by weight, and more preferably 15 parts by weight to 70 parts by weight.

### Solvent (D)

The solvent (D) needs to be able to completely dissolve other organic components, and the volatility thereof needs to be high enough such that a small thermal energy can evaporate the solvent (D) from the dispersion under normal pressure. Therefore, a solvent having a boiling point less than 150° C. under atmospheric pressure is most commonly used, and the solvent can be aromatic, such as benzene, toluene, and xylene; alcohol, such as methanol and ethanol; ether, such as ethylene glycol monopropyl ether, diglyme, tetrahydrofuran, ethylene glycol monomethyl ether, ethylene glycol monomethyl ether, diethylene glycol monomethyl ether, diethylene glycol monoethyl ether, diethylene glycol butyl ether; ester such as ethylene glycol monomethyl ether acetate, ethylene glycol monoethyl ether acetate, propylene glycol monomethyl ether acetate, propylene glycol monoethyl ether acetate, propylene glycol propyl ether acetate, ethyl 3-ethoxypropionate; ketone such as methyl ethyl ketone and acetone. In particular, diglyme, propylene glycol monomethyl ether acetate, and ethyl 3-ethoxypropionate are preferably used alone or two at a time, which is best for the storage stability of the negative photosensitive resin composition.

Based on a usage amount of 100 parts by weight of the alkali-soluble resin (A), the usage amount of the solvent (D) is 500 parts by weight to 3000 parts by weight, preferably 700 parts by weight to 2800 parts by weight, and more preferably 900 parts by weight to 2600 parts by weight.

### Silicone Compound (E)

The silicone compound (E) contains the structure represented by formula (E-1):

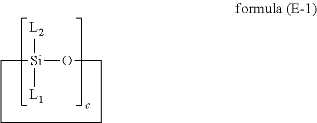

In formula (E-1), c is an integer of 3 to 7; L₁ and L₂ each independently represent a monovalent group containing an epoxy ester ring group or an alkyl group, a plurality of L₁ and L₂ can be the same or different, and in a c number of L₁ and L₂, at least one group is a monovalent group containing an epoxy ester ring group.

Specific examples of the silicone compound (E) can include the following compounds, but are not limited to the following specific examples: a silicone compound such as 2,4-bis[2-(3-{oxybicyclo[4.1.0]heptyl})ethyl]-2,4,6,6,8,8-hexamethyl cyclotetrapolysiloxane, 4,8-bis[2-(3-{oxybicyclo[4.1.0]heptyl})ethyl]-2,2,4,6,6,8-hexamethylcyclotetrapolysiloxane, 2,4-bis[2-(3-{oxybicyclo[4.1.0]heptyl})ethyl]-6,8-dipropyl-2,4,6,8-tetramethylcyclotetrapolysiloxane, 4,8-bis[2-(3-{oxybicyclo[4.1.0]heptyl})ethyl]-2,6-dipropyl-2,4,6,8-tetramethylcyclotetrapolysiloxane, 2,4,8-tris [2-(3-{oxybicyclo[4.1.0]heptyl})ethyl]-2,4,6,6,8-pentamethylcyclotetrapolysiloxane, 2,4,8-tris[2-(3-{oxybicyclo[4.1.0]heptyl})ethyl]-6-propyl-2,4,6,8-tetramethylcyclotetrapolysiloxane, 2,4,6,8-tetrakis[2-(3-{oxybicyclo[4.1.0]heptyl})ethyl]-2,4,6,8-tetramethylcyclotetrapolysiloxane, 2,4,6,8,10-penta[2-(3-{oxybicyclo[4.1.0]heptyl})ethyl]-2,4,6,8,10-pentamethylcyclopentapolysiloxane, 2,4,6,8,10,12,14-hepta[2-(3-{oxybicyclo [4.1.0]heptyl})ethyl]-2,4,6,8,10,12,14-heptamethylcycloheptapolysiloxane, or silsesquioxane having an alicyclic epoxy group.

More specifically, specific examples of the silicone compound (E) can also include silicone compounds represented by formula (E-1-1) to formula (E-1-9):

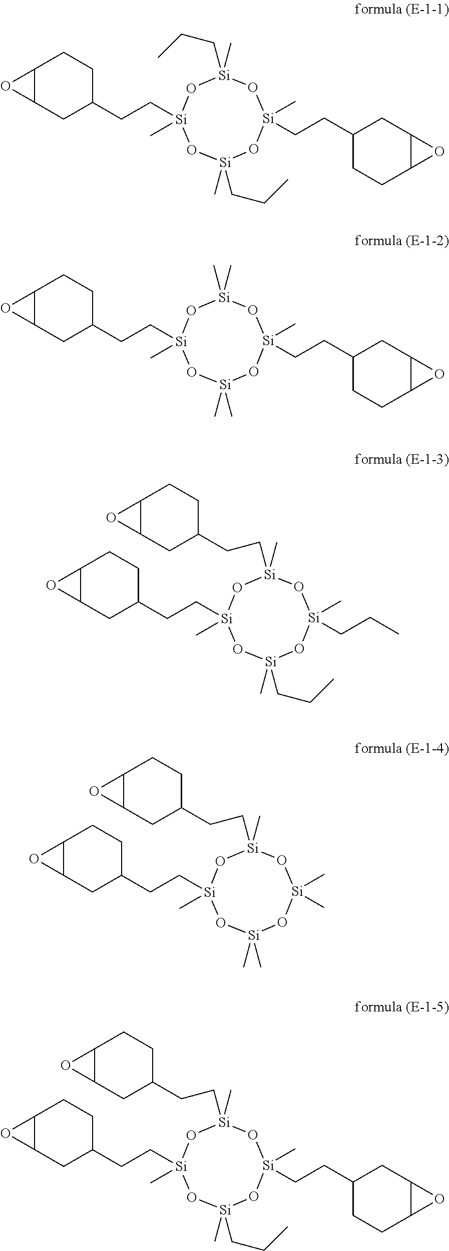 [SMILES: CCC[Si]1(C)O[Si](C)(CCC2CCC3OC3C2)O[Si](C)(CCC)O[Si](C)(CCC2CCC3OC3C2)O1 ; C[Si]1(C)O[Si](C)(CCC2CCC3OC3C2)O[Si](C)(C)O[Si](C)(CCC2CCC3OC3C2)O1 ; CCC[Si]1(C)O[Si](C)(CCC)O[Si](C)(CCC2CCC3OC3C2)O[Si](C)(CCC2CCC3OC3C2)O1 ; C[Si]1(C)O[Si](C)(C)O[Si](C)(CCC2CCC3OC3C2)O[Si](C)(CCC2CCC3OC3C2)O1 ; CCC[Si]1(C)O[Si](C)(CCC2CCC3OC3C2)O[Si](C)(CCC2CCC3OC3C2)O[Si](C)(CCC2CCC3OC3C2)O1]

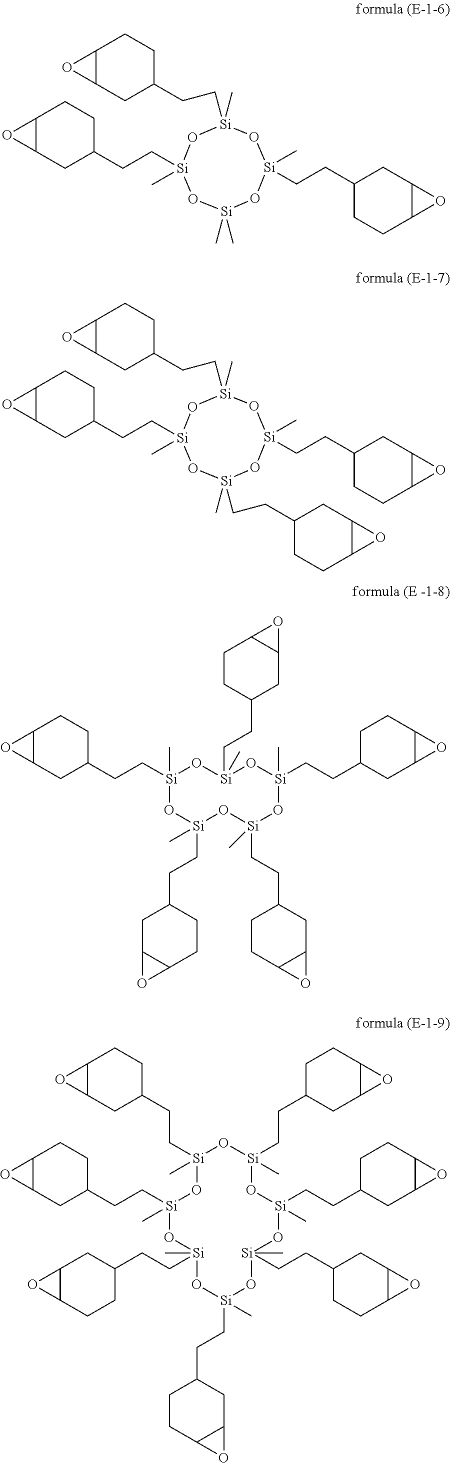 [SMILES: C[Si]1(C)O[Si](C)(CCC2CCC3OC3C2)O[Si](C)(CCC2CCC3OC3C2)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O[Si](C)(CCC2CCC3OC3C2)O1]

Based on a usage amount of 100 parts by weight of the alkali-soluble resin (A), the usage amount of the silicone compound (E) is 3 parts by weight to 25 parts by weight, preferably 3 parts by weight to 22 parts by weight, and more preferably 3 parts by weight to 20 parts by weight.

When the negative photosensitive resin composition does not contain the silicone compound (E), the sputtering resistance of the spacer or a protective film formed by the negative photosensitive resin composition is poor.

### Photoacid Generator (F)

The photoacid generator (F) is a compound capable of generating acid upon irradiation. Specifically, the photoacid generator (F) is, for instance, an onium salt compound, a halogen-containing compound, a sulfone compound, a sulfonic acid compound, a sulfonamido group, or a combination of the compounds.

The onium salt compound is, for instance, iodonium salt, sulfonium salt, phosphonium salt, diazonium salt, pyridinium salt, or a similar compound thereof. Specific examples of the onium salt compound include diphenyliodonium trifluoromethanesulfonate, diphenyliodonium p-toluenesulfonate, diphenyliodonium hexafluoroantimonate, diphenyliodonium hexafluorophosphate, diphenyliodonium tetrafluoroborate, triphenylsulfonium trifluoromethanesulfonate, triphenylsulfonium p-toluenesulfonate, triphenylsulfonium hexafluoroantimonate, 4-t-butylphenyl diphenylsulfonium trifluoromethanesulfonate, 4-t-butylphenyldiphenylsulfonium p-toluenesulfonate, 4,7-di-n-butoxy naphthyltetrahydrothiophenium trifluoromethanesulfonate, or a combination of the compounds.

Moreover, the onium salt compound can also be cyclohexylmethyl (2-oxocyclohexyl)sulfonium trifluoromethanesulfonate, dicyclohexyl(2-oxocyclohexyl) sulfoniumtrifluoromethane sulfonate, (2-oxocyclohexyl)(2-norbornyl)sulfoniumtrifluoromethanesulfonate, 2-cyclohexylsulfonyl cyclohexanone, dimethyl(2-oxocyclohexyl) sulfonium trifluoromethanesulfonate, N-hydroxy succinimide trifluoro methanesulfonate, phenyl p-toluenesulfonate, or a combination of the compounds.

The halogen-containing compound is, for instance, a haloalkyl-containing hydrocarbon compound or a haloalkyl-containing heterocyclic compound. Specific examples of the halogen-containing compound include 1,10-dibromo-n-decane, 1,1-bis(4-chlorophenyl)-2,2,2-trichloroethane, phenyl-bis(trichloro methyl)-s-triazine, 4-methoxyphenyl bis(trichloromethyl)-s-triazine, styryl bis(trichloromethyl)-s-triazine, naphthyl bis(trichloromethyl)-s-triazine, 2,4-bis(trichloromethyl)-6-p-methoxystyryl-s-triazine (TAZ-110), or similar s-triazine, or a combination of the compounds.

Moreover, the halogen-containing compound can also be tris(2,3-dibromopropyl)phosphate, tris(2,3-dibromo-3-chloropropyl)phosphate, tetrabromochlorobutane, 2-[2-(3,4-dimethoxyphenyl)ethenyl]-4,6-bis(trichloromethyl)-s-triazine, 2-[2-(4-methoxyphenyl)ethenyl]-4,6-bis(trichloromethyl)-s-triazine, hexachlorobenzene, hexabromobenzene, hexabromocyclododecane, hexabromocyclododecene, hexabromobiphenyl, allyltribromophenyl ether, tetrachlorobisphenol A, tetrabromobisphenol A, bis(chloroethyl)ether of tetrachlorobisphenol A, bis(bromoethyl)ether of tetrabromobisphenol A, bis(2,3-dichloropropyl)ether of bisphenol A, bis(2,3-dibromopropyl)ether of bisphenol A, bis(2,3-dichloro propyl)ether of tetrachlorobisphenol A, bis(2,3-dibromopropyl)ether of tetrabromobisphenol A, bis(chloroethyl)ether of the tetrachloro bisphenol S, tetrabromobisphenol S, tetrachlorobisphenol S, bis(bromoethyl)ether of tetrabromobisphenol S, bis(2,3-dichloropropyl)ether of the bisphenol S, bis(2,3-dichloropropyl)ether of the bisphenol S, tris(2,3-dibromopropyl)isocyanurate, 2,2-bis(4-hydroxy-3,5-dibromophenyl)propane, 2,2-bis(4-(2-hydroxyethoxy)-3,5-dibromophenyl)propane, or similar halogen series flame retardants.

The sulfone compound is, for instance, a β-ketosulfone compound, a β-sulfonyl sulfone compound, or an α-diazo compound of the compounds. Specific examples of the sulfone compound include 4-trisphenacyl sulfone, mesityl phenacyl sulfone, bis(phenacylsulfonyl)methane, or a combination of the compounds.

The sulfonic acid compound is, for instance, alkylsulfonic acid ester, haloalkylsulfonic acid ester, arylsulfonic acid ester, or iminosulfonate. Specific examples of the sulfonic acid compound include benzoin tosylate, pyrogalloltris(trifluoromethane sulfonate), o-nitrobenzyl trifluoromethanesulfonate, o-nitrobenzyl p-toluenesulfonate, or a combination of the compounds.

Specific examples of the sulfonamido compound include N-(trifluoromethylsulfonyloxy)succinimide, N-(trifluoromethylsulfonyloxy)phthalimide, N-(trifluoromethyl sulfonyloxy)diphenylmaleimide, N-(trifluoromethylsulfonyloxy) bicyclo[2.2.1]hept-5-ene-2,3-dicarboxyimide, N-(trifluoromethyl sulfonyloxy) naphthylimide (NAI-105), or a combination of the compounds.

The photoacid generator (F) is preferably 2,4-bis(trichloromethyl)-6-p-methoxy styryl-s-triazine (TAZ-110), N-(trifluoromethylsulfonyloxy) naphthylimide (NAI-105), triphenylsulfonium trifluoromethanesulfonate, or a combination of the compounds.

The photoacid generator (F) can be used alone or in multiple combinations.

Based on a usage amount of 100 parts by weight of the alkali-soluble resin (A), the usage amount of the photoacid generator (F) is 0.5 parts by weight to 5 parts by weight, preferably 0.5 parts by weight to 4 parts by weight, and more preferably 0.5 parts by weight to 3 parts by weight.

When the negative photosensitive resin composition contains the photoacid generator (F), the sputtering resistance of the spacer or a protective film formed by the negative photosensitive resin composition can be further increased.

### Additive (G)

Preferably, the negative photosensitive resin composition of the invention can further contain the additive (G) based on the desired physical properties and chemical properties, and the selection of the additive (G) can be decided by those having ordinary skill in the art of the invention. In a specific example of the invention, the additive (G) is, for instance, a filler, a polymer compound other than the alkali-soluble resin (A), a UV absorber, an anti-aggregating agent, a surfactant, an adhesion promoter, a storage stabilizer, or a heat resistance promoter.

In a preferred specific example of the invention, the filler is, for instance: glass, aluminum; the polymer compound other than the alkali-soluble resin (A) is, for instance, polyvinyl alcohol, polyethylene glycol monoalkyl ether, polyfluoro alkyl acrylate.

The UV absorber is, for instance, 2-(3-tert-butyl-5-methyl-2-hydroxyphenyl)-5-chlorophenyl azide, alkoxy phenone; the anti-coagulant is, for instance, sodium polyacrylate.

The surfactant can promote the coatability according to the composition of the invention, and in a specific example of the invention, the surfactant can adopt a fluorine-containing surfactant or an organic silicon surfactant.

In the fluorine-containing surfactant, the ends, main chain, and side chains thereof at least contain a fluoroalkyl group or a fluoroalkenyl group. In a specific example of the invention, the fluorine-containing surfactant is, for instance, 1,1,2,2-tetrafluorooctyl(1,1,2,2-tetrafluoro propyl)ether, 1,1,2,2-tetrafluorooctyl hexyl ether, octaethylene glycol di(1,1,2,2-tetrafluorobutyl)ether, hexaethylene glycol(1,1,2,2,3,3-hexafluoropentyl)ether, octaglycol di(1,1,2,2-tetrafluorobutyl)ether, hexapropylene glycol(1,1,2,2,3,3-hexafluoropentyl)ether, sodium perfluoro dodecyl sulfate, 1,1,2,2,8,8,9,9,10,10-decafluoro dodecane, 1,1,2,2,3,3-hexafluoro decane, sodium fluoroalkyl benzene sulfonate, sodium fluoroalkyl phosphate, sodium fluoroalkyl carboxylate, fluoroalkyl polyoxyethylene ether, dipropyl triol tetra(fluoroalkyl polyoxyethylene ether), fluoroalkyl amine iodine, fluoroalkyl betaine, fluoroalkyl polyoxyethylene ether, perfluoroalkyl polyoxyethylene ether, perfluoroalkyl alkanol. In another specific example of the invention, the fluorine-containing surfactant is, for instance, BM-1000, BM-1100 (made by BM CHEMIE), Megafac F142D, F172, F173, F183, F178, F191, F471, F476 (made by Dainippon Ink and Chemical Industries), Fluorad FC 170C, FC-171, FC-430, FC-431 (made by Sumitomo Chemical), chlorofluorocarbon S-112, S-113, S-131, S-141, S-145, S-382, SC-101, SC-102, SC-103, SC-104, SC-105, SC-106 (made by Asahi Glass), F Top EF301, 303, 352 (made by Daiwa Kasei), Ftergent FT-100, FT-110, FT-140A, FT-150, FT-250, FT-251, FTX-251, FTX-218, FT-300, FT-310, FT-400S (made by NEOSU).

The organic silicon surfactant is, for instance, TORE organosilicon DC3PA, DC7PA, SH11PA, SH21PA, SH28PA, SH29PA, SH30PA, SH-190, SH-193, SZ-6032, SF-8427, SF-8428, DC-57, DC-190 (made by Dow Corning Toray Silicone), TSF-4440 [symbol] TSF-4300, TSF-4445, TSF-4446, TSF-4460, TSF-4452 (made by Ge Toshiba Silicones).

Other than the fluorine-containing surfactant or organic silicon surfactant, the surfactant can also be polyoxyethylene alkyl ether such as polyoxyethylene lauryl ether, polyoxyethylene stearate ether, polyoxyethylene oleyl ether; polyoxyethylene aryl ether such as polyoxyethylene n-octyl phenyl ether, polyoxyethylene n-nonylphenol ether; polyoxyethylene dialkyl ester such as polyoxyethylene dilaurate, polyoxyethylene distearate; or a nonionic surfactant such as KP341 (made by Shin-Etsu Chemical), poly flow No. 57, 95 (made by Kyoeisha Yushi Kagaku Kogyo).

The surfactant can be used alone or in combination.

The adhesion promoter can improve the adhesion of the substrate, and is preferably a functional silane cross-linking agent, and preferably, the silane cross-linking agent contains a carboxyl group, an alkenyl group, an isocyanate group, an epoxy group, an amine group, a mercapto group, or halogen. Specific examples of the invention include p-hydroxyphenyl trimethoxy silane, 3-methacryloyloxy propyl trimethoxy silane, vinyl triacetyloxy silane, vinyl trimethoxy silane, vinyl triethoxy silane, vinyl tri(2-methoxyethoxy)silane, γ-isocyanate propyl triethoxy silane, 3-glycidoxypropyl trimethoxy silane, 2-(3,4-epoxycyclohexyl)ethyl trimethoxy silane, 3-glycidoxypropyl dimethyl methoxy silane, 3-aminopropyl trimethoxy silane, N-(2-aminoethyl)-3-amino propyl trimethoxy silane, N-(2-aminoethyl)-3-aminopropyl methyl dimethoxy silane, 3-mercaptopropyl trimethoxy silane, 3-chloropropyl trimethoxy silane, 3-chloropropyl methyl dimethoxy silane. Moreover, the adhesion promoter can also include, but is not limited to, SZ 6030 (made by Dow Corning Toray Silicone) and KBE-903, KBE-603, KBE-403, and KBM-403 (made by Shin-Etsu Chemical). The adhesion promoter can be used alone or in combination.

The storage stabilizer can be sulfur, quinone, hydroquinone, polyoxide, amine, a nitroso compound, or a nitro compound. Specific examples thereof include 4-methoxyphenol, (N-nitroso-N-phenyl)hydroxylamine aluminum, 2,2-thiobis(4-methyl-6-tert-butylphenol), 2,6-di-tert-butyl phenol.

The heat resistance promoter can be a N-(alkoxymethyl)glycoluril compound, N-(alkoxymethyl)melamine. Specific examples of the N-(alkoxymethyl)glycoluril compound include N,N,N′,N′-tetra(methoxymethyl)glycoluril, N,N,N′,N′-tetra (ethoxymethyl)glycoluril, N,N,N′,N′-tetra(n-propoxymethyl)glycoluril, N,N,N′,N′-tetra (isopropoxymethyl)glycoluril, N,N,N′,N′-tetra(n-butoxymethyl)glycoluril, N,N,N′,N′-tetra(tert-butoxymethyl)glycoluril; preferably N,N,N′,N′-tetra(methoxymethyl)glycoluril. Specific examples of N-(alkoxymethyl)melamine include N,N,N′,N′,N″,N″-hexakis (methoxymethyl)melamine, N,N,N′,N′,N″,N″-hexakis(ethoxymethyl)melamine, N,N,N′,N′,N″,N″-hexakis(n-propoxymethyl)melamine, N,N,N′,N′,N″,N″-hexakis (isopropoxymethyl)melamine, N,N,N′,N′,N″,N″-hexakis(n-butoxymethyl)melamine, N,N,N′,N′,N″,N″-hexakis(tert-butoxymethyl)melamine; preferably N,N,N′,N′,N″,N″-hexakis(methoxymethyl)melamine. Commercial products include, for instance, NIKARAKKU N-2702, MW-30M (made by Sanwa Chemical).

### <Production Method of Negative Photosensitive Resin Composition>

The production method of the negative photosensitive resin composition includes, for instance: placing and stirring the alkali-soluble resin (A), the compound (B) containing an ethylenically-unsaturated group, the photoinitiator (C), the solvent (D), and the silicone compound (E) in a stirrer such that the components are uniformly mixed into a solution state, and when needed, the photoacid generator (F) and the additive (G) can also be added. After the components are uniformly mixed, the negative photosensitive resin composition in solution state can be obtained.

In addition, the production method of the negative photosensitive resin composition is not particularly limited. The production method of the negative photosensitive resin composition includes, for instance, first dispersing a portion of the alkali-soluble resin (A) and the compound (B) containing an ethylenically-unsaturated group in a portion of the solvent (D) to form a dispersed solution; and then the rest of the alkali-soluble resin (A), the compound (B) containing an ethylenically-unsaturated group, the photoinitiator (C), the solvent (D), the silicone compound (E), the photoacid generator (F), and the additive (G) are added.

### <Forming of Protective Film and Spacer>

The invention provides a production method of a protective film and a production method of a spacer. A protective film or a spacer having a pattern is obtained by applying a pre-bake treatment, an exposure treatment, a developing treatment, and a post-bake treatment in order on the negative photosensitive resin composition. The production method thereof is described in detail below.

The production method of the protective film of the invention includes first forming a pixel layer composed of a red, a green, and a blue color layer on a transparent substrate, and then coating the negative photosensitive resin composition of the invention on the substrate on which red, green, and blue pixel color layers are formed. Then, steps such as pre-bake, exposure, development, and post-bake are performed to remove the solvent therein, so as to form a color filter layer protective film.

The production method of the spacer of the invention includes first forming a transparent conductive film on a transparent substrate on which a protective film and a pixel layer are formed, and then coating the negative photosensitive resin composition of the invention on the transparent conductive film. Then, steps such as pre-bake, exposure, development, and post-bake are performed to remove the solvent therein, so as to form the spacer.

In other words, if the protective film is to be formed, then the negative photosensitive resin composition is coated on the pixel layer on the substrate; and if the spacer is to be formed, then the negative photosensitive resin composition is coated on the transparent conductive film on the substrate.

The coating method can be, for instance, spray coating, roller coating, spin coating, bar coating, or ink jet coating. The coating method is preferably performed with, for instance, a spin coater, a spinless coating machine, and a slit-die coating machine.

Conditions of the pre-bake vary with the type and the mix ratio of each component. In general, the pre-bake is performed at a temperature of 70° C. to 90° C. for 1 minute to 15 minutes. After pre-bake, the thickness of the pre-baked coating film is 0.15 μm to 8.5 μm, preferably 0.15 μm to 6.5 μm, and more preferably 0.15 μm to 4.5 μm. It should be understood that the thickness of the pre-baked coating film refers to the thickness after the solvent is removed.

After the pre-baked coating film is formed, a heat treatment is performed with a heating apparatus such as a hot plate or an oven. The temperature of the heat treatment is generally 150° C. to 250° C., wherein the heating time is 5 minutes to 30 minutes when a hot plate is used, and the heating time is 30 minutes to 90 minutes when an oven is used.

When the curable resin composition contains the photoinitiator, if needed, an exposure treatment is performed on the pre-baked coating film after the curable resin composition is coated on the surface of the substrate and the solvent is removed with a pre-bake method to form the pre-baked coating film.

The light used for the exposure treatment can be, for instance, visible light, UV light, far-UV light, electron beam, X-ray. However, light containing UV light and having a wavelength of 190 nm to 450 nm is preferred.

The amount of exposure of the exposure treatment is preferably 100 J/m² to 20,000 J/m², but more preferably 150 J/m² to 10,000 J/m².

After the exposure treatment, a heat treatment can optionally be performed with a heating apparatus such as a hot plate or an oven. The temperature of the heat treatment is generally 150° C. to 250° C., wherein the heating time is 5 minutes to 30 minutes when a hot plate is used, and the heating time is 30 minutes to 90 minutes when an oven is used.

The protective film and the spacer of the invention are not limited to be formed on the pixel layer or the transparent conductive film, and can be formed on a substrate or various devices on the substrate.

### <Production Method of Color Filter>

Specifically, the production method of the color filter includes, for instance: performing sputtering on the surface of a protective film layer under a vacuum environment of a temperature between 220° C. and 250° C. to form an ITO protective film after red, green, and blue . . . etc. pixel color layers and the protective film are formed. If needed, etching is performed on the ITO protective film, and wiring is performed, and then an alignment film is coated on the ITO protective film surface, so as to produce a color filter of a cured product formed by curing the negative photosensitive resin composition of the invention.

### <Production Method of Liquid Crystal Display Device>

First, the color filter formed by the production method of a color filter and a substrate provided with a thin film transistor (TFT) are disposed opposite to each other, and a gap (cell gap) is left between the two. Then, the color filter and the peripheral portion of the substrate are adhered with an adhesive and an injection hole is left. Then, liquid crystal is injected into the gap separated by the substrate surface and the adhesive through the injection hole. Lastly, the injection hole is sealed to form a liquid crystal layer. Then, a polarizer is provided to the other side of the color filter in contact with the liquid crystal layer and the other side of the substrate in contact with the liquid crystal layer to produce a liquid crystal display apparatus. The liquid crystal used, i.e., a liquid crystal compound or a liquid crystal composition, is not particularly limited. Any liquid crystal compound or liquid crystal composition can be used.

Moreover, the liquid crystal alignment film used in the production of the color filter is used to limit the alignment of liquid crystal molecules and is not particularly limited. Both inorganic matter and organic matter can be used, and the invention is not limited thereto.

Examples are provided below to describe the invention in detail, but the invention is not limited to the contents disclosed in the examples.

### EXAMPLES

### Synthesis Examples of First Alkali-Soluble Resin (A-1)

In the following, synthesis example A-1-1 to synthesis example A-1-8 of the first alkali-soluble resin (A-1) are described:

### Synthesis Example A-1-1

A stirrer, a thermometer, a condenser tube, and a nitrogen inlet were provided to a four-necked flask, and nitrogen was introduced. Then, 100 parts by weight of propylene glycol monomethyl ether acetate (PGMEA) was added, and the temperature was increased to 100° C. Then, 3 parts by weight of a monomer (a-1-1), 10 parts by weight of methacrylate (MAA), 37 parts by weight of dicyclopentadiene methacrylate (FA-513M), 30 parts by weight of isobornyl methacrylate (IBOMA), 20 parts by weight of styrene (SM), and 4 parts by weight of 2,2′-azobis-2-methyl butyronitrile (AMBN) were dissolved in 100 parts by weight of propylene glycol monomethyl ether acetate (PGMEA), and the mixture was added dropwise in the four-necked flask within 2 hours, and after reacting at 100° C. for 6.5 hours, the first alkali-soluble resin (A-1-1) of synthesis example A-1-1 was obtained.

### Synthesis Example A-1-2 to Synthesis Example A-1-3

The alkali-soluble resins of synthesis example A-1-2 to synthesis example A-1-3 were prepared with the same steps as synthesis example A-1-1, and the difference thereof is: the component type and the amount, reaction time, and reaction temperature of the alkali-soluble resins were changed (as shown in Table 1).

### Synthesis Example A-1-4

A stirrer, a thermometer, a condenser tube, and a nitrogen inlet were provided to a four-necked flask, and nitrogen was introduced. Then, 100 parts by weight of ethyl 3-ethoxypropionate (EEP) was added, and the temperature was increased to 105° C. Then, 20 parts by weight of a monomer (a-1-4), 20 parts by weight of methacrylic acid (MAA), 10 parts by weight of acrylic acid (AA), 50 parts by weight of dicyclopentadiene methacrylate (FA-513M), and 4 parts by weight of 2,2′-azobis(2,4-dimethylvaleronitrile) (ADVN) were dissolved in 100 parts by weight of ethyl 3-ethoxypropionate (EEP), and the mixture was added dropwise in the four-necked flask within 2 hours. After reacting at 105° C. for 6.5 hours, 3 parts by weight of glycidyl methacrylate (GMA) was added to the four-necked flask filled with nitrogen, and the temperature was increased to 110° C. After reacting for 6 hours, the first alkali-soluble resin (A-1-4) of synthesis example A-1-4 was obtained.

### Synthesis Example A-1-5 to Synthesis Example A-1-8

The alkali-soluble resins of synthesis example A-1-5 to synthesis example A-1-8 were prepared with the same steps as synthesis example A-1-4, and the difference thereof is: the component type and the amount, reaction time, and reaction temperature of the alkali-soluble resins were changed (as shown in Table 1).

### Synthesis Examples of Other Alkali-Soluble Resins (A-2)

In the following, synthesis example A-2-1 to synthesis example A-2-6 of the other alkali-soluble resins (A-2) are described:

### Synthesis Example A-2-1

4 parts by weight of 2,2′-azobis-2-methylbutyronitrile (AMBN), 240 parts by weight of propylene glycol monomethyl ether acetate (PGMEA), 50 parts by weight of methacrylic acid (MAA), 20 parts by weight of dicyclopentadiene methacrylate (FA-513M), 20 parts by weight of isobornyl methacrylate (IBOMA), and 10 parts by weight of styrene (SM) were placed in a round-bottomed flask provided with a stirrer and a condenser, and the flask was filled with nitrogen. Next, the components were slowly stirred and the temperature was raised to 80° C. such that each of the reactants was uniformly mixed, and then a polymerization reaction was performed for 4.5 hours. Then, the temperature was further raised to 100° C. and 0.5 parts by weight of 2,2′-azobisisobutyronitrile (AMBN) was added. After a polymerization reaction was performed for 1 hour, the other alkali-soluble resins (A-2-1) were obtained.

### Synthesis Example A-2-2 to Synthesis Example A-2-5

The alkali-soluble resins of synthesis example A-2-2 to synthesis example A-2-5 were prepared with the same steps as synthesis example A-2-1, and the difference thereof is: the component type and the amount, reaction time, and reaction temperature of the alkali-soluble resins were changed (as shown in Table 2).

### Synthesis Example A-2-6

5 parts by weight of 2,2′-azobis-2,4-dimethylvaleronitrile (ADVN) and 200 parts by weight of ethylene glycol methylethyl ether were placed in a round-bottomed flask provided with a stirrer and a condenser, and then 20 parts by weight of methacrylic acid (MAA), 45 parts by weight of glycidyl methacrylate, 10 parts by weight of styrene (SM), and 25 parts by weight of cyclopentyl (meth)acrylate were added, and the flask was filled with nitrogen. Next, the components were slowly stirred and the temperature was raised to 70° C. such that each of the reactants was uniformly mixed, and then a polymerization reaction was performed for 5 hours to obtain the other alkali-soluble resins (A-2-6). The concentration of the other alkali-soluble resins (A-2-6) was 33.3 wt %, and the weight-average molecular weight thereof was 9,000.

Moreover, the compounds corresponding to the abbreviations in Table 1 and Table 2 are as shown below.

| Abbreviation | Compound |
|---|---|
| a-1-1 | In the monomer represented by formula (A1-1-1), R₄ represents a methyl group. |
| | 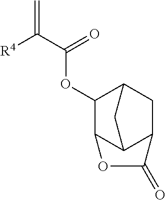 |
| a-1-2 | In the monomer represented by formula (A1-1-2), R₄ represents a methyl group. |
| | 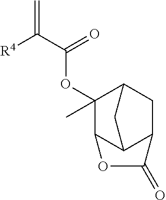 |
| a-1-3 | In the monomer represented by formula (A1-1-6), R₄ represents a methyl group. |
| | 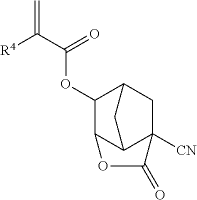 |
| a-1-4 | In the monomer represented by formula (A1-1-9), R represents a methyl group. |
| | 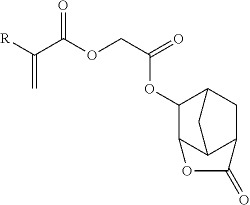 |
| a-1-5 | In the monomer represented by formula (A1-1-15), R represents a methyl group. |
| | 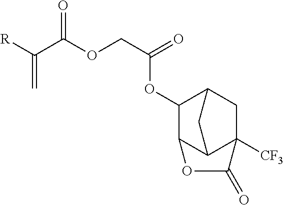 |
| a-1-6 | In the monomer represented by formula (A1-1-24), R represents a methyl group. |
| | 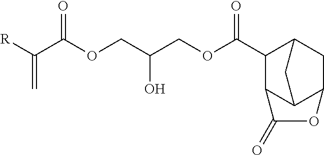 |
| a-1-7 | In the monomer represented by formula (A1-1-25), R represents a methyl group. |
| | 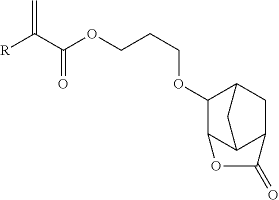 |
| a-1-8 | In the monomer represented by formula (A1-1-27), R represents a methyl group. |
| | 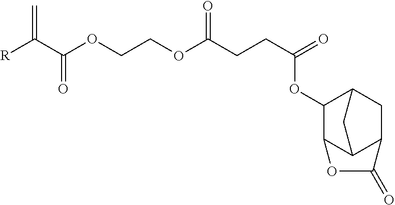 |
| MAA | Methacrylic acid |
| AA | Acrylic acid |
| HOMS | 2-methacryloyloxyethyl succinate |
| HEMA | Hydroxyethyl methacrylate |
| FA-513M | Dicyclopentanyl methacrylate |
| BzMA | Benzyl methacrylate |
| IBOMA | Isobornyl methacrylate |
| SM | Styrene monomer |
| GMA | Glycidyl methacylate |
| ECM-MA | 3,4-epoxycyclohexylmethyl methacrylate |
| EP-MA | 6,7-epoxyheptyl methacrylate |
| AMBN | 2,2′-azobis(2-methylbutyronitrile) |
| ADVN | 2,2′-azobis(2,4-dimethylvaleronitrile) |
| PGMEA | Propylene glycol monomethyl ether acetate |
| EEP | Ethyl 3-ethoxypropionate |

TABLE 1

| Component (parts by | | | | | | | | | | |
|---|---|---|---|---|---|---|---|---|---|---|
| weight) | | | A-1-1 | A-1-2 | A-1-3 | A-1-4 | A-1-5 | A-1-6 | A-1-7 | A-1-8 |
| Monomer for | a1 -I | a-1-1 | 3 | — | — | — | — | — | — | — |
| copolymerization | | a-1-2 | — | 5 | 10 | — | — | 10 | — | — |
| | | a-1-3 | — | — | 5 | — | — | — | — | — |
| | | a-1-4 | — | — | — | 20 | — | — | — | — |
| | | a-1-5 | — | — | — | — | 25 | — | — | — |
| | | a-1-6 | — | — | — | — | — | 20 | — | — |
| | | a-1-7 | — | — | — | — | — | — | 10 | — |
| | | a-1-8 | — | — | — | — | — | — | — | 8 |
| | a1-II | MAA | 10 | — | — | 20 | — | — | — | — |
| | | AA | — | 15 | — | 10 | 35 | — | 25 | — |
| | | HOMS | — | — | 20 | — | — | 40 | — | 25 |
| | a1-III | HEMA | — | 10 | — | — | — | 30 | — | — |
| | | FA-513M | 37 | 40 | — | 50 | — | — | — | — |
| | | BzMA | — | 30 | 45 | — | — | — | 50 | — |
| | | IBOMA | 30 | — | 20 | — | 10 | — | — | 17 |
| | | SM | 20 | — | — | — | 30 | — | 15 | 50 |
| | a1-IV | GMA | — | — | — | 3 | 5 | — | — | — |
| | | ECM-MA | — | — | — | — | 5 | — | 20 | — |
| | | EP-MA | — | — | — | — | — | 15 | — | 30 |
| Initiator | | AMBN | 4 | 4.5 | 4 | — | — | 4.5 | 4.5 | 4.5 |
| | | ADVN | — | — | — | 4.5 | 4 | — | — | — |
| Solvent | | PGMEA | 200 | 200 | 200 | — | 200 | — | — | — |
| | | EEP | — | — | — | 200 | — | 200 | 200 | 200 |

| | | | | | | | | |
|---|---|---|---|---|---|---|---|---|
| Reaction temperature | 100 | 105 | 100 | 105 | 100 | 105 | 105 | 105 |
| (° C.) | | | | | | | | |
| Polymerization time | 6.5 | 6 | 6 | 6.5 | 6 | 6 | 6 | 6 |
| (hours) | | | | | | | | |

TABLE 2

| Component (parts by | | | | | | | |
|---|---|---|---|---|---|---|---|
| weight) | | | A-2-1 | A-2-2 | A-2-3 | A-2-4 | A-2-5 |
| Monomer for | a2-I | MAA | 50 | — | — | 10 | — |
| copolymerization | | AA | — | 40 | — | 10 | — |
| | | HOMS | — | — | 30 | — | 5 |
| | a2-II | HEMA | — | 30 | — | — | 5 |
| | | FA-513M | 20 | — | 15 | — | — |
| | | BzMA | — | 20 | 5 | 70 | — |
| | | IBOMA | 20 | 10 | — | 10 | — |
| | | SM | 10 | — | 50 | — | 90 |
| Initiator | | AMBN | 4.5 | 5 | — | — | — |
| | | ADVN | — | — | 4.5 | 5 | 5 |
| Solvent | | PGMEA | 240 | 250 | — | — | — |
| | | EEP | — | — | 240 | 240 | 250 |

| | | | | | |
|---|---|---|---|---|---|
| Reaction temperature | 80 | 85 | 80 | 85 | 85 |
| (° C.) | | | | | |
| Polymerization time | 4.5 | 4 | 4 | 4 | 4.5 |
| (hours) | | | | | |

### Examples of Negative Photosensitive Resin Composition

Example 1 to example 16 and comparative example 1 to comparative example 5 of the negative photosensitive resin composition are described below:

### Example 1

100 parts by weight of the alkali-soluble resin of synthesis example A-2-1 (hereinafter A-2-1), 60 parts by weight of dipentaerythritol hexaacrylate (hereinafter B-1), 60 parts by weight of 1-[4-(phenylthio)phenyl]-octane-1,2-dione 2-(O-benzoyloxime) (hereinafter C-1), 60 parts by weight of 2,4-bis[2-(3-{oxabicyclo[4.1.0]heptyl})ethyl]-2,4,6,6,8,8-hexamethyl cyclic tetramer siloxane (hereinafter E-1) were added in 700 parts by weight of propylene glycol monomethyl ether acetate (hereinafter D-1), and after stirring uniformly with a shaking-type stirrer, the negative photosensitive resin composition of example 1 was obtained. The obtained negative photosensitive resin composition was evaluated by the following evaluation methods, and the results are as shown in Table 3.

### Example 2 to Example 16

The negative photosensitive resin compositions of example 2 to example 16 were prepared using the same steps as example 1, and the difference thereof is: the type and the usage amount of the components of the negative photosensitive resin compositions were changed (as shown in Table 3, Table 4). The obtained negative photosensitive resin compositions were evaluated by the following evaluation methods, and the results are as shown in Table 3, Table 4.

### Comparative Example 1 to Comparative Example 4

The negative photosensitive resin compositions of comparative example 1 to comparative example 4 were prepared using the same steps as example 1, and the difference thereof is: the type and the usage amount of the components of the negative photosensitive resin compositions were changed (as shown in Table 4). The obtained negative photosensitive resin compositions were evaluated by the following evaluation methods, and the results are as shown in Table 4.

### Comparative Example 5

100 parts by weight of the alkali-soluble resin of synthesis example A-2-6, 20 parts by weight of dipentaerythritol hexaacrylate, 80 parts by weight of dipentaerythritol pentaacrylate, 20 parts by weight of 1,2-diacetyl-1-[4-(methylthio)phenyl]2-(O-acetyl oxime), and 5 parts by weight of 1-[4-(methylthio)phenyl]-2-methyl-2-morpholin-1-one were added in propylene glycol monomethyl ether acetate at a solid concentration of 35 wt %, and after stirring uniformly with a shaking-type stirrer, filtering was performed with a microporous filter having an aperture of 0.2 μm to obtain the negative photosensitive resin composition of comparative example 5. The obtained negative photosensitive resin composition was evaluated by the following evaluation methods, and the results thereof are X.

Moreover, the compounds corresponding to the abbreviations in Table 3 and Table 4 are as shown below.

| Abbreviation | Compound |
|---|---|
| A-1-1 | First alkali-soluble resin of synthesis example A-1-1 |
| A-1-2 | First alkali-soluble resin of synthesis example A-1-2 |
| A-1-3 | First alkali-soluble resin of synthesis example A-1-3 |
| A-1-4 | First alkali-soluble resin of synthesis example A-1-4 |
| A-1-5 | First alkali-soluble resin of synthesis example A-1-5 |
| A-1-6 | First alkali-soluble resin of synthesis example A-1-6 |
| A-1-7 | First alkali-soluble resin of synthesis example A-1-7 |
| A-1-8 | First alkali-soluble resin of synthesis example A-1-8 |
| A-2-1 | Other alkali-soluble resins of synthesis example A-2-1 |
| A-2-2 | Other alkali-soluble resins of synthesis example A-2-2 |
| A-2-3 | Other alkali-soluble resins of synthesis example A-2-3 |
| A-2-4 | Other alkali-soluble resins of synthesis example A-2-4 |
| A-2-5 | Other alkali-soluble resins of synthesis example A-2-5 |
| B-1 | Dipentaerythritol hexaacrylate |
| B-2 | Dipentaerythritol tetraacrylate |
| B-3 | Dipentaerythritol pentaacrylate |
| C-1 | 1-[4-(phenylthio)phenyl]-octane-1,2-dione 2-(O-benzoyloxime) |
| | (product: OXE-01, made by Ciba Specialty Chemicals) |
| C-2 | 2-benzyl-2-N,N-dimethylamine-1-(4-morpholinophenyl)-1-butanone |
| | (product: IRGACURE 369; made by Ciba Specialty Chemicals) |
| C-3 | 2-methyl-1-[4-(methylthio)phenyl]-2-morpholino-1-propanone |
| | (product: IRGACURE 907; made by Ciba Specialty Chemicals) |
| D-1 | Propylene glycol monomethyl ether acetate (PGMEA) |
| D-2 | Ethyl 3-ethoxypropionate (EEP) |
| D-3 | Cyclohexanone |
| E-1 | 2,4-bis[2-(3-{oxabicyclo[4.1.0]heptyl})ethyl]-2,4,6,6,8,8- |
| | hexamethylcyclotetrapolysiloxane |
| E-2 | 4,8-bis[2-(3-{oxabicyclo[4.1.0]heptyl})ethyl]-2,2,4,6,6,8- |
| | hexamethylcyclotetrapolysiloxane |
| E-3 | 2,4-bis[2-(3-{oxabicyclo[4.1.0]heptyl})ethyl]-6,8-dipropyl-2,4,6,8- |
| | tetramethylcyclotetrapolysiloxane |
| E-4 | 2,4,8-tris[2-(3-{oxabicyclo[4.1.0]heptyl})ethyl]-2,4,6,6,8- |
| | pentamethylcyclotetrapolysiloxane |
| E-5 | 2,4,8-tris[2-(3-{oxabicyclo[4.1.0]heptyl})ethyl]-6-propyl-2,4,6,8- |
| | tetramethylcyclotetrapolysiloxane |
| E-6 | 2,4,6,8-tetra[2-(3-{oxabicyclo[4.1.0]heptyl})ethyl]-2,4,6,8- |
| | tetramethylcyclotetrapolysiloxane |
| E-7 | 2,4,6,8,10-penta[2-(3-{oxabicyclo[4.1.0]heptyl})ethyl]-2,4,6,8,10- |
| | pentamethylcyclopentapolysiloxane |
| E-8 | 2,4,6,8,10,12,14-hepta[2-(3-{oxabicyclo[4.1.0]heptyl})ethyl]- |
| | 2,4,6,8,10,12,14-heptamethylcycloheptapolysiloxane |
| F-1 | Diphenyliodonium trifluoromethanesulfonate |
| F-2 | 2,4-bis(trichloromethyl)-6-p-methoxystyryl-s-triazine (TAZ-110) |
| F-3 | Mesityl phenacyl sulfone |
| F-4 | o-nitrobenzyl trifluoromethanesulfonate |
| F-5 | N-(trifluoromethyl sulfonyloxy)naphthylimide (NAI-105) |
| G-1 | Trimethoxysilyl propanethiol |
| G-2 | 2,2′-thiobis(4-methyl-6-tert-butyl-phenol) |
| G-3 | Alkoxy phenone |

### Evaluation Methods

Sputtering Resistance

An 80 mm×80 mm coating film was coated on a 100 mm×100 mm rectangular glass substrate using the negative photosensitive resin composition via a screen printing machine (made by Dongwon Unitech, AT-45PA). After post-bake, the photoresist film thickness was 2.2 μm to 2.3 μm, and ITO coating was performed via a plasma cleaning machine at an output power of 600 W for 15 minutes and a press of 100 mtorr using oxygen (flow rate: 100 sccm), and the film thickness after sputtering was measured, and then evaluation of sputtering resistance was performed according to the following formula.

Sputtering resistance=(film thickness after sputtering/film thickness after post-bake)*100%

The criteria for sputtering resistance is as follows:

: sputtering resistance≧90%

⊚: 85%≦sputtering resistance<90%

∘: 80%≦sputtering resistance<85%

Δ: 75%≦sputtering resistance<80%

X: sputtering resistance<75%

TABLE 3

| Component | | | Example | | | | | | | | | |
|---|---|---|---|---|---|---|---|---|---|---|---|---|
| (parts by weight) | | | 1 | 2 | 3 | 4 | 5 | 6 | 7 | 8 | 9 | 10 |
| Alkali-soluble | A-1 | A-1-1 | — | — | 50 | — | — | — | — | — | — | — |
| resin (A) | | A-1-2 | — | — | — | 20 | — | — | — | — | — | — |
| | | A-1-3 | — | — | — | 40 | — | — | — | — | — | 100 |
| | | A-1-4 | — | — | — | — | — | — | — | — | 70 | — |
| | | A-1-5 | — | — | — | — | — | — | — | — | — | — |
| | | A-1-6 | — | — | — | — | — | — | — | — | — | — |
| | | A-1-7 | — | — | — | — | — | — | — | — | 20 | — |
| | | A-1-8 | — | — | — | — | — | — | — | — | — | — |
| | A-2 | A-2-1 | 100 | — | — | — | — | 50 | 100 | — | — | — |
| | | A-2-2 | — | 100 | — | — | 10 | 50 | — | 100 | — | — |
| | | A-2-3 | — | — | 50 | — | 90 | — | — | — | — | — |
| | | A-2-4 | — | — | — | 40 | — | — | — | — | 10 | — |
| | | A-2-5 | — | — | — | — | — | — | — | — | — | — |
| Compound | | B-1 | 60 | — | — | 150 | — | — | 120 | — | — | 150 |
| (B) | | B-2 | — | 90 | — | — | 180 | — | 120 | — | 200 | — |
| containing | | B-3 | — | — | 120 | — | — | 210 | — | 300 | 70 | 150 |
| an | | | | | | | | | | | | |
| ethylenically- | | | | | | | | | | | | |
| unsaturated group | | | | | | | | | | | | |
| Photoinitiator | | C-1 | 60 | — | — | 75 | — | — | 15 | — | — | 30 |
| (C) | | C-2 | — | 65 | — | — | 80 | — | — | 20 | — | — |
| | | C-3 | — | — | 70 | — | — | 10 | — | — | 25 | — |
| Solvent (D) | | D-1 | 700 | — | — | 700 | — | 500 | 1900 | — | — | 2500 |
| | | D-2 | — | 900 | — | 600 | 1000 | — | — | 2100 | — | |
| | | D-3 | — | — | 1100 | — | 500 | 1200 | — | — | 2300 | — |
| Silicone | | E-1 | 10 | — | — | — | — | — | — | — | — | — |
| compound | | E-2 | — | 12 | — | — | — | — | 25 | — | — | — |
| (E) | | E-3 | — | — | 15 | — | — | — | — | 3 | — | — |
| | | E-4 | — | — | — | 18 | — | — | — | — | — | 5 |
| | | E-5 | — | — | — | — | 20 | — | — | — | — | — |
| | | E-6 | — | — | — | — | — | 22 | — | — | — | 5 |
| | | E-7 | — | — | — | — | — | — | — | — | — | — |
| | | E-8 | — | — | — | — | — | — | — | — | 8 | — |
| Photoacid | | F-1 | — | — | — | — | — | — | — | — | 5 | — |
| generator | | F-2 | — | — | — | — | 3 | — | — | — | — | — |
| (F) | | F-3 | — | — | — | — | — | 4 | — | — | — | — |
| | | F-4 | — | — | — | — | — | — | — | — | — | — |
| | | F-5 | — | — | — | — | — | — | — | — | — | — |
| Additive | | G-1 | — | — | — | — | 5 | — | 10 | — | — | 8 |
| (G) | | G-2 | — | — | — | — | 1 | 4 | — | — | 2 | — |
| | | G-3 | — | — | — | — | — | 3 | — | — | — | — |

| | | | | | | | | | | |
|---|---|---|---|---|---|---|---|---|---|---|
| Sputtering resistance | ○ | ○ | ⊚ | ⊚ | ⊚ | ⊚ | ○ | ○ | | ⊚ |
| evaluation | | | | | | | | | | |

TABLE 4

| Component | | | Example | | | | | | Comparative example | | | |
|---|---|---|---|---|---|---|---|---|---|---|---|---|
| (parts by weight) | | | 11 | 12 | 13 | 14 | 15 | 16 | 1 | 2 | 3 | 4 |
| Alkali-soluble | A-1 | A-1-1 | — | — | — | — | — | — | — | — | — | — |
| resin (A) | | A-1-2 | — | — | — | — | — | — | — | — | — | — |
| | | A-1-3 | — | — | — | — | — | — | — | — | — | — |
| | | A-1-4 | — | — | — | — | — | — | — | — | — | — |
| | | A-1-5 | — | — | — | 20 | — | — | — | — | — | — |
| | | A-1-6 | — | — | 30 | — | — | — | — | — | — | — |
| | | A-1-7 | — | — | — | — | — | — | — | — | — | — |
| | | A-1-8 | — | — | — | — | 10 | — | — | — | — | — |
| | A-2 | A-2-1 | 20 | — | — | — | 90 | — | 100 | | — | — |
| | | A-2-2 | 80 | — | — | 80 | — | — | — | 100 | — | — |
| | | A-2-3 | — | — | 70 | — | — | 100 | — | — | — | 100 |
| | | A-2-4 | — | 60 | — | — | — | — | — | — | 40 | — |
| | | A-2-5 | — | 40 | — | — | — | — | — | — | 60 | — |

| | | | | | | | | | | | |
|---|---|---|---|---|---|---|---|---|---|---|---|
| Compound | B-1 | 100 | — | — | 70 | 50 | — | 60 | — | — | — |
| (B) | B-2 | — | 30 | — | — | 200 | — | — | 90 | 30 | — |
| containing | B-3 | — | — | 50 | — | — | 200 | — | — | — | 200 |
| an | | | | | | | | | | | |
| ethylenically- | | | | | | | | | | | |
| unsaturated | | | | | | | | | | | |
| group | | | | | | | | | | | |
| Photoinitiator | C-1 | — | 10 | — | 25 | — | — | 60 | — | 10 | — |
| (C) | C-2 | 35 | — | 30 | 25 | — | 60 | — | 65 | — | 60 |
| | C-3 | — | 30 | 15 | — | 55 | — | — | — | 30 | — |
| Solvent (D) | D-1 | — | — | 500 | — | 1000 | — | 700 | — | — | — |
| | D-2 | 2700 | — | — | 3000 | — | 2000 | — | 900 | — | 2000 |
| | D-3 | — | 2900 | — | — | 1000 | — | — | — | 2900 | — |
| Silicone | E-1 | 8 | — | — | — | 10 | — | — | — | — | — |
| compound | E-2 | 4 | 10 | — | 5 | — | 2 | — | — | — | — |
| (E) | E-3 | — | 5 | 10 | — | — | — | — | — | — | — |
| | E-4 | — | — | — | 15 | — | — | — | — | — | — |
| | E-5 | — | — | — | — | 15 | 3 | — | — | — | — |
| | E-6 | — | — | — | — | — | — | — | — | — | — |
| | E-7 | — | — | 8 | — | — | — | — | — | — | — |
| | E-8 | — | — | — | — | — | — | — | — | — | — |
| Photoacid | F-1 | — | — | — | 0.5 | — | — | — | — | — | — |
| generator | F-2 | 0.5 | — | 1 | — | 3.5 | — | — | — | — | — |
| (F) | F-3 | — | — | — | 0.5 | — | — | — | — | — | — |
| | F-4 | — | — | 1 | — | — | — | — | — | — | — |
| | F-5 | — | — | — | — | 1 | — | — | — | — | — |
| Additive | G-1 | — | — | — | — | — | — | — | — | — | — |
| (G) | G-2 | 9 | — | — | — | 1 | — | — | — | — | — |
| | G-3 | — | — | — | — | 2 | — | — | — | — | — |

| | | | | | | | | | | |
|---|---|---|---|---|---|---|---|---|---|---|
| Sputtering resistance | ⊚ | ○ | | | | ○ | [symbol] | [symbol] | [symbol] | [symbol] |
| evaluation | | | | | | | | | | |

### Evaluation Results

It can be known from Table 3 and Table 4 that, in comparison to the negative photosensitive resin compositions (examples 1 to 16) of the siloxane compound (E) containing the structure represented by formula (E-1), the sputtering resistance evaluation of the spacer or a protective film formed by the negative photosensitive resin compositions of comparative examples 1 to 4 is poor.

Moreover, the sputtering resistance evaluation of the spacer or a protective film formed by the negative photosensitive resin composition of comparative example 5 is also poor.

Moreover, when the alkali-soluble resin (A) in the negative photosensitive resin composition includes the first alkali-soluble resin (A-1) having the repeating unit represented by formula (A1-1) (examples 3, 4, 9, 10, 13 to 15), the sputtering resistance evaluation of the spacer or a protective film formed by the negative photosensitive resin composition is better.

Moreover, the sputtering resistance evaluation of the spacer or a protective film formed by the negative photosensitive resin composition using the first alkali-soluble resin (A-1) having an ethylenically-unsaturated group (examples 9, 13 to 15) is better.

Moreover, when the negative photosensitive resin composition further contains the photoacid generator (F) (examples 5, 6, 9, 11, 13 to 15), the sputtering resistance evaluation of the spacer or a protective film formed by the negative photosensitive resin composition is also better.

Based on the above, the negative photosensitive resin composition of the invention contains the silicone compound (E) of the structure represented by formula (E-1), and therefore the issue of poor sputtering resistance of the spacer or a protective film formed by the negative photosensitive resin composition can be solved.

Moreover, if the negative photosensitive resin composition of the invention further contains the first alkali-soluble resin (A-1) having the repeating unit represented by formula (A-1) or the photoacid generator (F), the sputtering resistance thereof can be further increased. Moreover, if the negative photosensitive resin composition of the invention further contains the first alkali-soluble resin (A-1) having an ethylenically-unsaturated group, the sputtering resistance thereof can be further increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A negative photosensitive resin composition, comprising:
an alkali-soluble resin (A);
a compound (B) containing an ethylenically-unsaturated group;
a photoinitiator (C);
a solvent (D); and
a silicone compound (E),
wherein the silicone compound (E) contains a structure represented by formula (E-1): 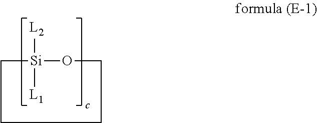
in formula (E-1), c is an integer of 3 to 7; L₁ and L₂ each independently represent a monovalent group containing an epoxy ester ring group or an alkyl group, a plurality of L₁ and L₂ can be the same or different, and in a c number of L₁ and L₂, at least one group is a monovalent group containing an epoxy ester ring group.

2. The negative photosensitive resin composition of claim 1, wherein the alkali-soluble resin (A) comprises a first alkali-soluble resin (A-1), and the first alkali-soluble resin (A-1) has a repeating unit represented by formula (A1-1); 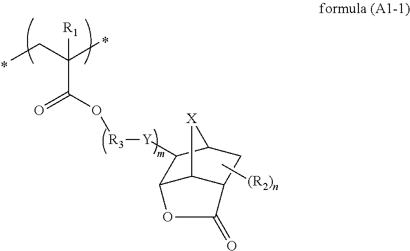
in formula (A1-1), R¹ represents a hydrogen atom or an alkyl group;
R₂ represents an alkyl group, a cycloalkyl group, an alkoxy group, an alkoxycarbonyl group, a carboxyl group, a halogen atom, a hydroxyl group, or a cyano group; R₃ represents an alkylene group, a cycloalkylene group, or a combination thereof, and when formula (A1-1) has 2 or more R₃, each R₃ can be the same or different;
Y represents a single bond, —O—, —COO—, —CONH—, —NHCOO—, or —NHCONH—, when formula (A1-1) has 2 or more Y, each Y can be the same or different; X represents methylene, methyl methylene, dimethyl methylene, ethylene, —O—, or —S—;
m and n each independently represent an integer of 0 to 4, when n is 2 or more, an n number of R₂ can be the same or different; * represents a bonding site.

3. The negative photosensitive resin composition of claim 2, wherein the first alkali-soluble resin (A-1) has an ethylenically-unsaturated group.

4. The negative photosensitive resin composition of claim 1, further comprising a photoacid generator (F).

5. The negative photosensitive resin composition of claim 1, wherein based on a usage amount of 100 parts by weight of the alkali-soluble resin (A), a usage amount of the compound (B) containing an ethylenically-unsaturated group is 30 parts by weight to 300 parts by weight, a usage amount of the photoinitiator (C) is 10 parts by weight to 80 parts by weight, a usage amount of the solvent (D) is 500 parts by weight to 3000 parts by weight, and a usage amount of the silicone compound (E) is 3 parts by weight to 25 parts by weight.

6. The negative photosensitive resin composition of claim 2, wherein based on a usage amount of 100 parts by weight of the alkali-soluble resin (A), a usage amount of the first alkali-soluble resin (A-1) is 3 parts by weight to 100 parts by weight.

7. The negative photosensitive resin composition of claim 4, wherein based on a usage amount of 100 parts by weight of the alkali-soluble resin (A), a usage amount of the photoacid generator (F) is 0.5 parts by weight to 5 parts by weight.

8. A production method of a spacer, wherein a spacer having a pattern is obtained by applying a pre-bake treatment, an exposure treatment, a developing treatment, and a post-bake treatment in order on the negative photosensitive resin composition of claim 1.

9. A production method of a protective film, wherein a protective film having a pattern is obtained by applying a pre-bake treatment, an exposure treatment, a developing treatment, and a post-bake treatment in order on the negative photosensitive resin composition of claim 1.

10. A liquid crystal display device, comprising the spacer obtained by the production method of a spacer of claim 8.

11. A liquid crystal display device, comprising the protective film obtained by the production method of a protective film of claim 9.
